(19) United States
(12) Patent Application Publication
(10) Pub. No.: US 2013/0007563 A1
(43) Pub. Date: Jan. 3, 2013

(54) SEMICONDUCTOR MEMORY DEVICE HAVING ERROR CORRECTION FUNCTION AND MEMORY SYSTEM INCLUDING THE SAME

(75) Inventor: Jong-Wook Park, Suwon-si (KR)

(73) Assignee: SAMSUNG ELECTRONICS CO., LTD., Suwon-si (KR)

(21) Appl. No.: 13/538,231

(22) Filed: Jun. 29, 2012

Related U.S. Application Data
(60) Provisional application No. 61/503,662, filed on Jul. 1, 2011.

(30) Foreign Application Priority Data
Feb. 20, 2012 (KR) 10-2012-0017090

(51) Int. Cl. H03M 13/29; G06F 11/10; H03M 13/05

(52) U.S. Cl. 714/758; 714/763; 714/E11.032

(57) ABSTRACT

The device may include a check bit generator, a memory cell array, an error calculator, and an error corrector. The check bit generator may generate check bits based on input data. The memory cell array may store combined data including the input data and the check bits. The error calculator may be configured to generate syndrome bits based on first data and the check bits received from the memory cell array, calculate an error based on the syndrome bits, and generate error data. The error corrector may be configured to correct the first data based on the error data, and generate second data. The check bits and syndrome bits may include normal check bits, additional check bits, normal syndrome bits, and additional syndrome bits, where the additional check bits are not be normal check bits, and the additional syndrome bits are not normal syndrome bits.

### CROSS-REFERENCE TO RELATED APPLICATION

This application claims priority under 35 U.S.C. §119 to Korean Patent Application No. 10-2012-0017090 filed on Feb. 20, 2012, in the Korean Intellectual Property Office (KIPO), the entire contents of which are incorporated herein by reference.

### BACKGROUND

1. Field

Embodiments of the inventive concepts relate to a semiconductor device, and more particularly, to an error corrector of a semiconductor memory device.

2. Description of Related Art

With the increase in capacity of semiconductor memory devices, deterioration of reliability and yield has become problematic. Accordingly, an error recovery circuit configured to recover or suppress errors in a defective memory cell may be desirable. In general, an error recovery circuit may be divided into a redundancy type and an error checking and correcting (ECC) type. When there is a defect in a normal cell, a redundancy-type error recovery circuit may replace the normal cell with a redundancy cell, while an ECC-type error recovery circuit may generate a parity bit based on input data, correct the error, and output data. A hamming code is typically used for the ECC circuit. The hamming code may detect errors and correct data error.

### SUMMARY

Embodiments of the inventive concepts provide a semiconductor memory device having an error correction function, which may have high operating speed and occupy a small chip size.

Embodiments of the inventive concepts provide a memory system including the semiconductor memory device.

In accordance with embodiments of the inventive concepts, a semiconductor memory device is provided. The device may include a check bit generator, a memory cell array, an error calculator, and an error corrector.

The check bit generator may be configured to generate check bits based on input data. The memory cell array may store combined data including the input data and the check bits. The error calculator may generate syndrome bits based on first data and the check bits received from the memory cell array, calculate an error based on the syndrome bits, and generate error data. The error corrector may correct the first data based on the first data and the error data, and generate second data. The check bit generator may be configured to generate one or more normal check bits and one or more additional check bits, and the error calculator maybe configured to generate one or more normal syndrome bits and one or more additional syndrome bits.

A function of the additional syndrome bits may have common elements that construct functions of the normal syndrome bits.

The error calculator may include a syndrome bit generating circuit configured to generate the syndrome bits based on the first data and the check bits.

The memory cell array may be configured to store the combined data such that the one or more normal check bits are disposed in positions having position numbers in the combined data which are powers of 2, and the one or more additional check bits are not disposed in positions having position numbers in the combined data which are powers of 2.

The check bit generator may be configured such that the normal check bits may include check bits C01, C02, C04, C08, C16, C32, and C64, and the one or more additional check bits may include a check bit C07.

The check bit generator may be configured to perform an exclusive OR (XOR) logic operation on selected data bits to generate the additional check bit C07, the selected data bits being data bits having position numbers within the combined data that correspond to binary numbers in which the three least significant bits represent the decimal number 7.

The check bit generator may compare data bits except for data bits disposed in a space where each of position numbers 1, 2, and 4 has the value “1”, and generate the check bits C01, C02, and C04.

The memory cell array may be configured to store the combined data such that the one or more normal check bits are disposed in positions having position numbers in the combined data which are powers of 2, and the one or more additional check bits are not disposed in positions having position numbers in the combined data which are powers of 2, and the error calculator may be configured to generate the one or more normal syndrome bits and the one or more additional syndrome bits such that each of the normal syndrome bits correspond to one of the normal check bits, and each of the additional syndrome bits corresponds to one of the additional check bits.

The error calculator may be configured such that the one or more normal syndrome bits may include syndrome bits S01, S02, S04, S08, S16, S32, and S64, and the one or more additional syndrome bits may include a syndrome bit S07.

The error calculator may be configured to generate one normal syndrome bit S64 of the normal syndrome bits, combine the normal syndrome bit S64 with even-first or odd-first first information to generate additional information regarding the normal syndrome bit S64, and use the additional information instead of the existing information regarding the normal syndrome bit S64 to calculate errors.

The error calculator may be configured such that the syndrome bit S64 may include a syndrome bit S64F obtained based on even data, and a syndrome bit S64S obtained based on odd data.

The error calculator may be configured to select one of the syndrome bits S64S and S64F based on ordering information including information regarding even-first data or odd-first data, and correct the error data based on the selected syndrome bit S64S or S64F.

The semiconductor memory device may be a stack memory device in which a plurality of chips are stacked. The stack memory chip may transmit and receive data, and control signals to and from one another through through-silicon vias (TSVs).

According to example embodiments of the inventive concepts, A semiconductor memory device may include a check bit generator configured to generate a plurality of check bits based on input data; and a memory cell array configured to store combined data, the combined data including the input data and the plurality of check bits, each bit in the combined data being placed at different one of a plurality of sequentially numbered bit positions within the combined data. The plurality of check bits may include one or more normal check bits having bit positions, from among the plurality of bit positions, the numbers of which are powers of 2, and the plurality of check bits may include additional check bits having bit positions, from among the plurality of bit positions, the numbers of which are not powers of 2.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram of a semiconductor memory device having an error correction function according to example embodiments of the inventive concepts;

FIGS. 2 and 3 are tables showing an example of a method of disposing check bits and data bits used in the semiconductor memory device of FIG. 1 according to position numbers, in accordance with example embodiments of the inventive concepts;

FIG. 4 is a table showing an example of a method of generating check bits using the data bits shown in FIGS. 2 and 3 according to example embodiments of the inventive concepts;

FIG. 5 is a table showing an example of a method of generating syndrome bits using the data bits shown in FIGS. 2 and 3 according to example embodiments of the inventive concepts;

FIGS. 6 and 7 are tables rewritten by adding a position number 7 to the tables shown in FIGS. 2 and 3 according to example embodiments of the inventive concepts;

FIGS. 8 and 9 are, respectively, circuit diagrams of circuits configured to generate a check bit C01 shown in FIG. 4 and a syndrome bit S01 shown in FIG. 5 using a plurality of exclusive OR gates according to example embodiments of the inventive concepts;

FIGS. 10 and 11 are, respectively, circuit diagrams of circuits configured to generate a check bit C02 and a syndrome bit S02 shown in FIG. 5 using a plurality of XOR gates according to example embodiments of the inventive concepts;

FIGS. 12 and 13 are, respectively, circuit diagrams of circuits configured to generate a check bit C04 shown in FIG. 4 and a syndrome bit S04 shown in FIG. 5 using a plurality of XOR gates according to example embodiments of the inventive concepts;

FIGS. 14 and 15 are, respectively, circuit diagrams of circuits configured to generate a check bit C07 shown in FIG. 4, and a syndrome bit S07 shown in FIG. 5 using a plurality of XOR gates according to example embodiments of the inventive concepts;

FIGS. 16 and 17 are, respectively, circuit diagrams of circuits configured to generate a check bit C08 and a syndrome bit C08 shown in FIG. 5 using a plurality of XOR gates according to example embodiments of the inventive concepts;

FIGS. 18 and 19 are, respectively, circuit diagrams of circuits configured to generate a check bit C16 shown in FIG. 4 and a syndrome bit S16 shown in FIG. 5 using a plurality of XOR gates according to example embodiments of the inventive concepts;

FIGS. 20 and 21 are, respectively, circuit diagrams of circuits configured to generate a check bit C32 and a syndrome bit S32 shown in FIG. 5 using a plurality of XOR gates according to example embodiments of the inventive concepts;

FIGS. 22 and 23 are, respectively, circuit diagrams of circuits configured to generate a check bit C64 and a syndrome bit S64 shown in FIG. 5 using a plurality of XOR gates according to example embodiments of the inventive concepts;

FIGS. 24 and 25 are tables showing an example of a method of disposing check bits and data bits used in a conventional semiconductor memory device according to position numbers;

FIG. 26 is a table showing an example of a method of generating check bits using the data bits shown in FIGS. 24 and 25;

FIG. 27 is a circuit diagram of a circuit configured to generate a syndrome bit S01 shown in the table of FIG. 26 using a plurality of XOR gates;

FIG. 28 is a diagram of an example of a data write path of the semiconductor memory device of FIG. 1 according to example embodiments of the inventive concepts;

FIG. 29 is a diagram of an example a data read path of the semiconductor memory device of FIG. 1 according to example embodiments of the inventive concepts;

FIG. 30 is a diagram showing a relationship between write data and read data when a semiconductor memory device has an even-first data output structure according to example embodiments of the inventive concepts;

FIG. 31 is a diagram showing a relationship between write data and read data when a semiconductor memory device has an odd-first data output structure according to example embodiments of the inventive concepts;

FIGS. 32 and 33 are tables showing an example of disposition of data including data ordering information and check bits in the tables shown in FIGS. 6 and 7 according to example embodiments of the inventive concepts;

FIG. 34 is a table showing an example of a method of generating check bits based on ordering information according to example embodiments of the inventive concepts;

FIG. 35 is a table showing an example of a method of generating check bits using data bits shown in FIGS. 32 and 33 according to example embodiments of the inventive concepts;

FIG. 36 is a table showing an example of a method of generating syndrome bits using the data bits shown in FIGS. 32 and 33 according to example embodiments of the inventive concepts;

FIGS. 37 through 52 are circuit diagrams of circuits configured to generate check bits shown in FIG. 35, and syndrome bits shown in FIG. 36 using a plurality of XOR gates according to example embodiments of the inventive concepts;

FIG. 53 is a table showing an example of a method of generating syndrome bits S64F and S64S using the data bits shown in FIGS. 32 and 33 according to example embodiments of the inventive concepts;

FIGS. 54 and 55 are circuit diagrams of circuits configured to generate syndrome bits shown in FIG. 53 using a plurality of XOR gates according to example embodiments of the inventive concepts;

FIG. 56 is a plan view of a memory module on which a semiconductor memory device is mounted, according to embodiments of the inventive concepts;

FIG. 57 is a simplified perspective view of one of stack semiconductor devices including semiconductor memory devices according to embodiments of the inventive concepts;

FIG. 58 is a block diagram of an example of a memory system including a semiconductor memory device according to embodiments of the inventive concepts; and

FIG. 59 is a block diagram of an example of an electronic system including a semiconductor memory device according to embodiments of the inventive concepts.

### DETAILED DESCRIPTION OF THE EMBODIMENTS

Detailed example embodiments of the inventive concepts are disclosed herein. However, specific structural and functional details disclosed herein are merely representative for purposes of describing example embodiments of the inventive concepts. Example embodiments of the inventive concepts may, however, be embodied in many alternate forms and should not be construed as limited to only the embodiments set forth herein.

Accordingly, while example embodiments of the inventive concepts are capable of various modifications and alternative forms, embodiments thereof are shown by way of example in the drawings and will herein be described in detail. It should be understood, however, that there is no intent to limit example embodiments of the inventive concepts to the particular forms disclosed, but to the contrary, example embodiments of the inventive concepts are to cover all modifications, equivalents, and alternatives falling within the scope of example embodiments of the inventive concepts. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the inventive concepts. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the inventive concepts. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

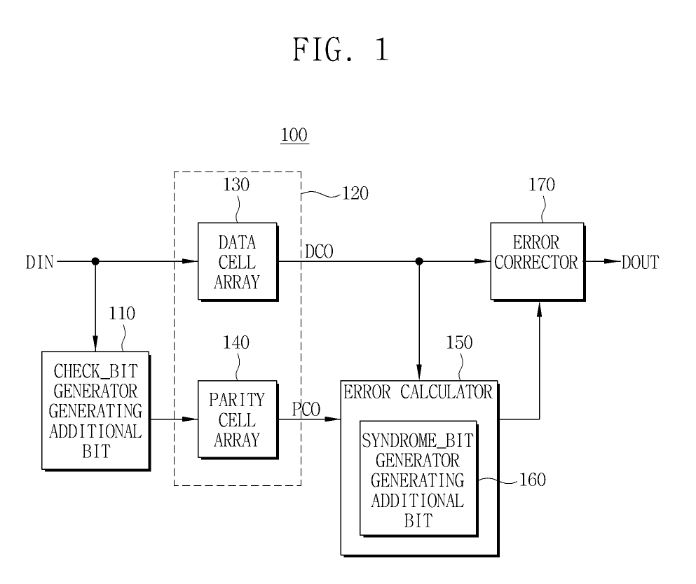

FIG. 1 is a block diagram of a semiconductor memory device 100 having an error correction function according to embodiments of the inventive concepts.

Referring to FIG. 1, the semiconductor memory device 100 may include a check bit generator 110, a memory cell array 120, an error calculator 150, and an error corrector 170.

The check bit generator 110 may generate check bits based on input data DIN, and the memory cell array 120 may store the input data DIN and the check bits. The memory cell array 120 may include a data cell array 130 configured to store the input data DIN, and a parity cell array 140 configured to store the check bits. The error calculator 150 may generate syndrome bits based on first data and check bits PCO received from the memory cell array 120, calculate an error based on the syndrome bits, and generate error data. The error corrector 170 may correct the first data DCO based on the first data DCO and the error data, and generate second data DOUT.

The check bit generator 110 may generate normal check bits and an additional check bit, and the error calculator 150 may generate normal syndrome bits and an additional syndrome bit. The error calculator 150 may include a syndrome bit generating circuit configured to generate the syndrome bits based on the first data DCO and the check bits PCO.

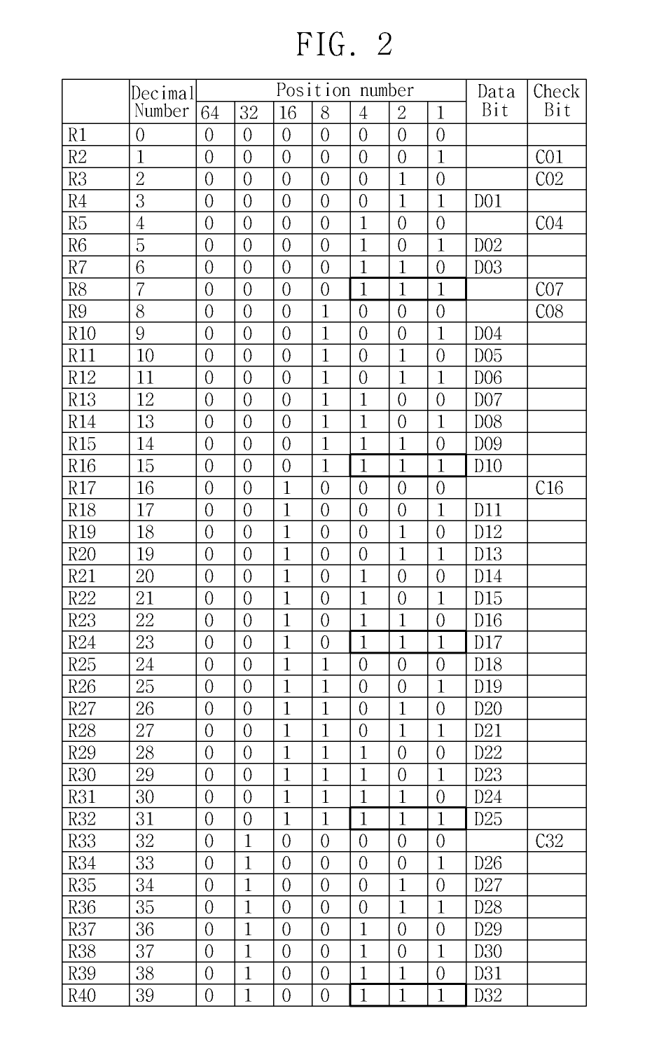

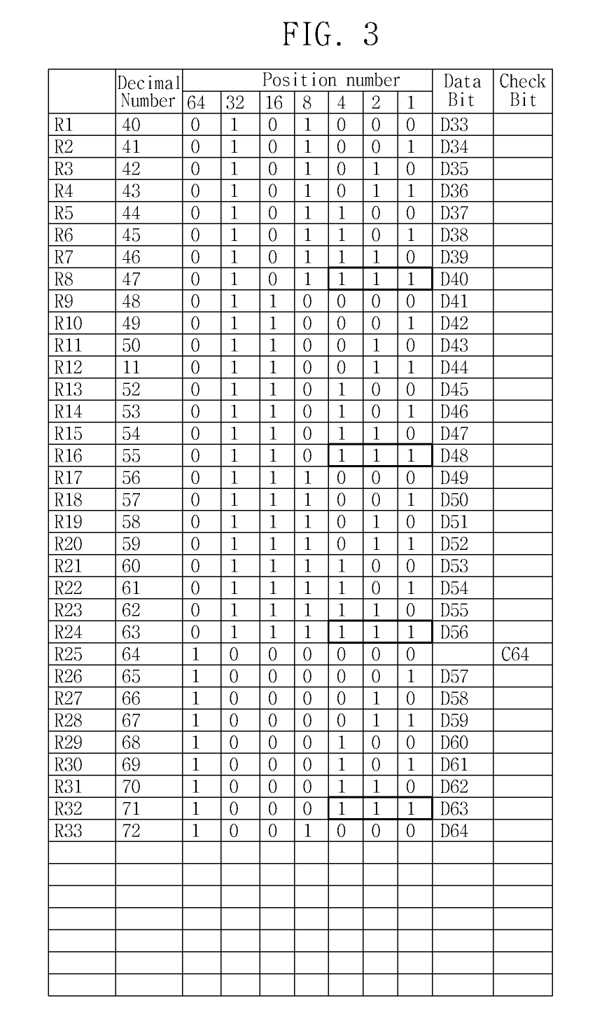

FIGS. 2 and 3 are tables showing an example of a method of disposing check bits and data bits used in the semiconductor memory device of FIG. 1 according to position numbers. FIGS. 2 and 3 show a method of disposing check bits and data bits according to position numbers when input data DIN input to a semiconductor memory device 100 is 64bits.

Referring to FIGS. 2 and 3, position numbers may include numbers based on a binary number system. That is, the position numbers may include 1, 2, 4, 8, 16, 32, and 64, each of which represents a power of 2. According to example embodiments of the inventive concepts, position numbers which correspond to a power of 2 may be defined as normal, and position numbers which do not correspond to a power of 2 may be defined as not normal. A least significant bit (LSB) position number may be 1, and a most significant bit (MSB) position number may be 64.

In FIGS. 2 and 3, decimal numbers 0 to 72 may be denoted by binary numbers according to the position numbers. Decimal numbers 0 to 39 may be arranged in rows R1 to R40 in FIG. 2, while decimal numbers 40 to 72 may be arranged in rows R1 to R33 in FIG. 3. Data bits may include 64 bits D01 to D64, and check bits may include eighth bits C01, C02, C04, C07, C08, C16, C32, and C64. In FIGS. 2 and 3, C07, which corresponds to a space where each of position numbers 1, 2, and 4 has a value “1”, may be illustrated with a solid block. According to example embodiments of the inventive concepts, check bits which correspond to a number which is a power of 2, including for example check bits C01, C02, C04, C08, C16, C32, and C64, may be defined as normal check bits. Check bits which do not correspond to numbers which are powers of 2, including for example check bit C07, may be defined as not being normal check bits.

C01 may be disposed in a space where a position number 1 has a value “1”, that is, a space of a binary number “0000001”. C02 may be disposed in a space where a position number 2 has a value “1”, that is, a space of a binary number “0000010”. C04 may be disposed in a space where a position number 4 has a value “1”, that is, a space of a binary number“0000100”. C08 may be disposed in a space where a position number 8 has a value “1”, that is, a space of a binary number “0001000”. C16 may be disposed in a space where a position number 16 has a value “1”, that is, a space of a binary number “0010000”. C32 may be disposed in a space where a position number 32 has a value“1”, that is, a space of a binary number “0100000”. C64 may be disposed in a space where a position number 64 has a value “1”, that is, a space of a binary number “1000000”. C07 may be disposed in a space where each of position numbers 1, 2, and 4 has a value “1” and each of position numbers 8, 16, 32, and 64 has a value “0”, that is, a space of a binary number “0000111”. The data bits D01 to D64 may be arranged in a sequential order in a space where the check bits C01, C02, C04, C07, C08, C16, C32, and C64 are not disposed.

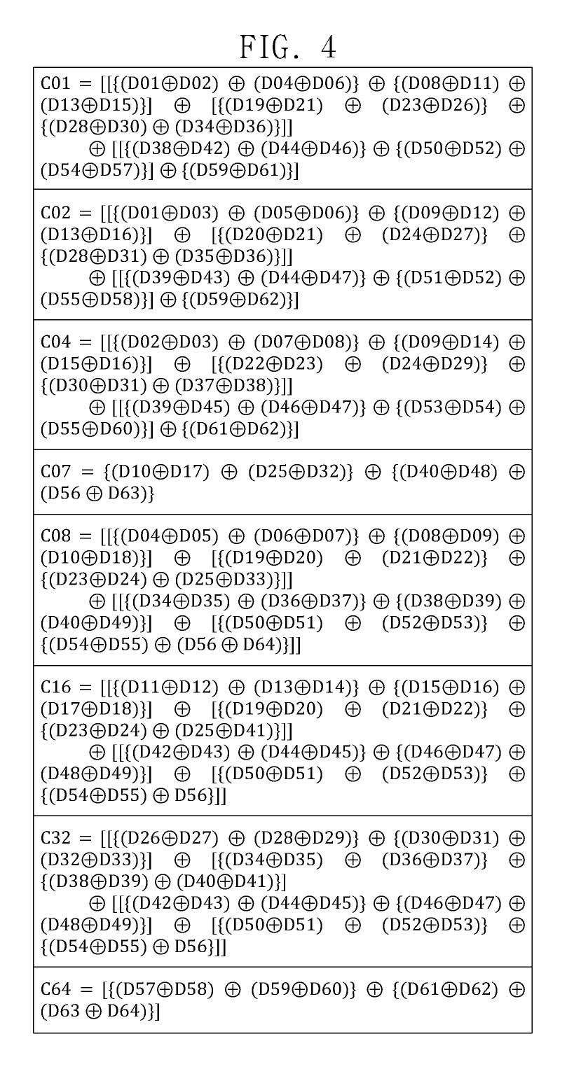

FIG. 4 is a table showing an example of a method of generating check bits using the data bits shown in FIGS. 2 and 3, and FIG. 5 is a table showing an example of a method of generating syndrome bits using the data bits shown in FIGS. 2 and 3.

Hereinafter, methods of generating check bits and syndrome bits according to embodiments of the inventive concepts will be described with reference to FIGS. 2 through 5.

C07 may be obtained by comparing data bits D10, D17, D25, D32, D40, D48, D56, and D63 arranged in a space where the position number 1 has a value “1”, out of the entire space of the decimal numbers 0 to 72. The comparison of the data bits D10, D17, D25, D32, D40, D48, D56, and D63 may be performed using an exclusive OR (XOR) operation. Referring to FIG. 4, C07 may be calculated using a logic expression: {D10 ⊕ D17) ⊕ (D25 ⊕ D32)} ⊕ {(D40 ⊕ D48) ⊕ (D56 ⊕ D63)}.

C01 may be obtained by comparing the data bits D01, D02, D04, D06, D08, D11, D13, D15, D19, D21, D23, D26, D28, D30, D34, D36, D38, D42, D44, D46, D50, D52, D54, D57, D59, and D61 that may be obtained by excluding the data bits D10, D17, D25, D32, D40, D48, D56, and D63 arranged in the space where each of the position numbers 1, 2, and 4 has a value “1” from the data bits D01, D02, D04, D06, D08, D10, D11, D13, D15, D17, D19, D21, D23, D25, D26, D28, D30, D32, D34, D36, D38, D40, D42, D44, D46, D48 D50, D52, D54, D56, D57, D59, D61, D63 arranged in the space where the position number 1 has the value “1” out of the entire space of the decimal numbers 0 to 71. As shown in FIG. 4, C01 may be obtained by performing a logic XOR on the data bits D01, D02, D04, D06, D08, D11, D13, D15, D19, D21, D23, D26, D28, D30, D34, D36, D38, D42, D44, D46, D50, D52, D54, D57, D59, and D61.

C02 may be obtained by comparing the data bits D01, D03, D05, D06, D09, D12, D13, D16, D20, D21, D24, D27, D28, D31, D35, D36, D39, D43, D44, D47, D51, D52, D55, D58, D59, and D62 that may be obtained by excluding the data bits D10, D17, D25, D32, D40, D48, D56, and D63 arranged in the space where each of the position numbers 1, 2, and 4 has a value “1” from the data bits D01, D03, D05, D06, D09, D10, D12, D13, D16, D17, D20, D21, D24, D25, D27, D28, D31, D32, D35, D36, D39, D40, D43, D44, D47, D48, D51, D52, D55, D56, D58, D59, D62, and D63 arranged in a space where the position number 2 has a value “1” out of the entire space of the decimal numbers 0 to 72. As shown in FIG. 4, C02 may be obtained by performing a logic XOR on the data bits D01, D03, D05, D06, D09, D12, D13, D16, D20, D21, D24, D27, D28, D31, D35, D36, D39, D43, D44, D47, D51, D52, D55, D58, D59, and D62.

C04 may be obtained by comparing the data bits D02, D03, D07, D08, D09, D14, D15, D16, D22, D23, D24, D29, D30, D31, D37, D38, D39, D45, D46, D47, D53, D54, D55, D60, D61, and D62 that may be obtained by excluding the data bits D10, D17, D25, D32, D40, D48, D56, and D63 arranged in the space where each of the position numbers 1, 2, and 4 has a value “1” from the data bits D02, D03, D07, D08, D09, D10, D14, D15, D16, D17, D22, D23, D24, D25, D29, D30, D31, D32, D37, D38, D39, D40, D45, D46, D47, D48, D53, D54, D55, D56, D60, D61, D62, and D63 arranged in a space where the position number 4 has a value “1” out of the entire space of the decimal numbers 0 to 72. As shown in FIG. 4, C04 may be obtained by performing a logic XOR on the data bits D02, D03, D07, D08, D09, D14, D15, D16, D22, D23, D24, D29, D30, D31, D37, D38, D39, D45, D46, D47, D53, D54, D55, D60, D61, and D62.

C08 may be obtained by comparing the data bits D04, D05, D06, D07, D08, D09, D10, D18, D19, D20, D21, D22, D23, D24, D25, D33, D34, D35, D36, D37, D38, D39, D40, D49, D50, D51, D52, D53, D54, D55, D56, and D64 arranged in a space where the position number 8 has a value “1” out of the entire space of the decimal numbers 0 to 72. As shown in FIG. 4, C08 may be obtained by performing a logic XOR on the data bits D04, D05, D06, D07, D08, D09, D10, D18, D19, D20, D21, D22, D23, D24, D25, D33, D34, D35, D36, D37, D38, D39, D40, D49, D50, D51, D52, D53, D54, D55, D56, and D64.

C16 may be obtained by comparing the data bits D11, D12, D13, D14, D15, D16, D17, D18, D19, D20, D21, D22, D23, D24, D25, D41, D42, D43, D44, D45, D46, D47, D48, D49, D50, D51, D52, D53, D54, D55, and D56 arranged in a space where the position number 16 has a value “1” out of the entire space of the decimal numbers 0 to 72. As shown in FIG. 4, C16 may be obtained by performing a logic XOR on the data bits D11, D12, D13, D14, D15, D16, D17, D18, D19, D20, D21, D22, D23, D24, D25, D41, D42, D43, D44, D45, D46, D47, D48, D49, D50, D51, D52, D53, D54, D55, and D56.

C32 may be obtained by comparing the data bits D26, D27, D28, D29, D30, D31, D32, D33, D34, D35, D36, D37, D38, D39, D40, D41, D42, D43, D44, D45, D46, D47, D48, D49, D50, D51, D52, D53, D54, D55, and D56 arranged in a space where the position number 32 has a value “1” out of the entire space of the decimal numbers 0 to 72. As shown in FIG. 4, C32 may be obtained by performing a logic XOR on the data bits D26, D27, D28, D29, D30, D31, D32, D33, D34, D35, D36, D37, D38, D39, D40, D41, D42, D43, D44, D45, D46, D47, D48, D49, D50, D51, D52, D53, D54, D55, and D56.

C64 may be obtained by comparing the data bits D57, D58, D59, D60, D61, D62, D63, and D64 arranged in a space where the position number 64 has a value “1” out of the entire space of the decimal numbers 0 to 72. As shown in FIG. 4, C64 may be obtained by performing a logic XOR on the data bits D57, D58, D59, D60, D61, D62, D63, and D64. For instance, S07 may be obtained by comparing the data bits D10, D17, D25, D32, D40, D48, D56, and D63 and the check bit C07 arranged in the space where the position number 1 has the value “1” out of the entire space of the decimal numbers 0 to 72. A comparison between the data bits may be performed using an XOR operation. Referring to FIG. 4, C07 may be obtained using a logic expression: {(D10 ⊕ D17) ⊕ (D25 ⊕ D32)} ⊕{(D40 ⊕ D48) ⊕ (D56 ⊕ D63)}.

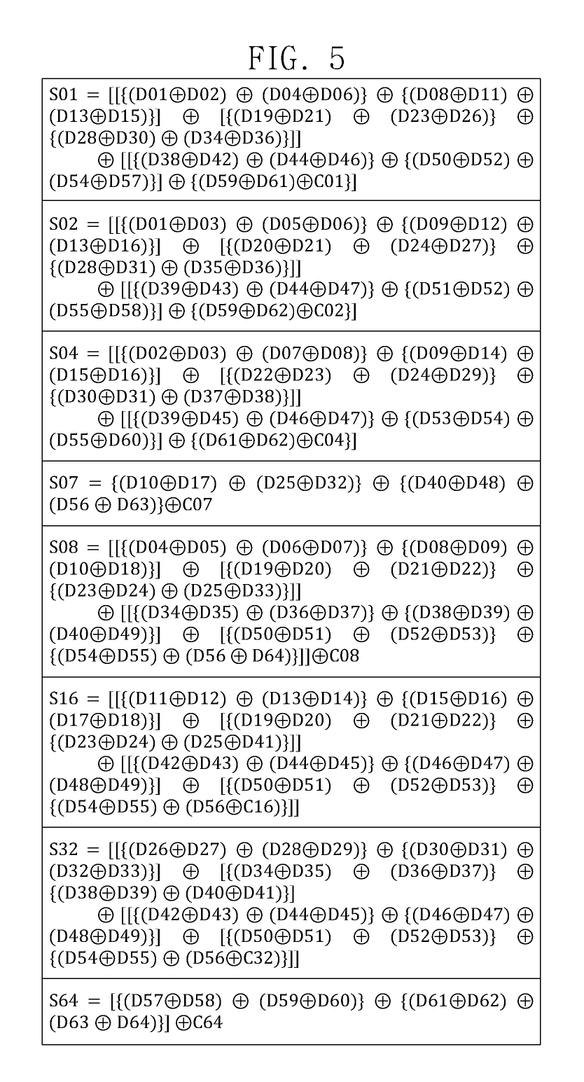

Referring to FIG. 5, syndrome bits S01, S02, S04, S07, S08, S16, S32, and S64 may be obtained by performing a logic XOR on the data bits used to obtain the corresponding check bits C01, C02, C04, C07, C08, C16, C32, and C64 and the corresponding check bits C01, C02, C04, C07, C08, C16, C32, and C64, respectively. According to example embodiments of the inventive concepts, syndrome bits which correspond to a number which is a power of 2, including for example syndrome bits S01, S02, S04, S08, S16, S32, and S64, may be defined as normal syndrome bits. Syndrome bits which do not correspond to numbers which are powers of 2, including for example check bit S07, may be defined as not being normal syndrome bits. Normal syndrome bits may be defined as syndrome bits generated based on normal check bits. Syndrome bits generated based on check bits which are not normal check bits may be defined as not being normal syndrome bits.

The number of all the syndrome bits including the additional syndrome bits is equal to the smallest unit of data quantity simultaneously output during a dynamic random access memory (DRAM) core operation.

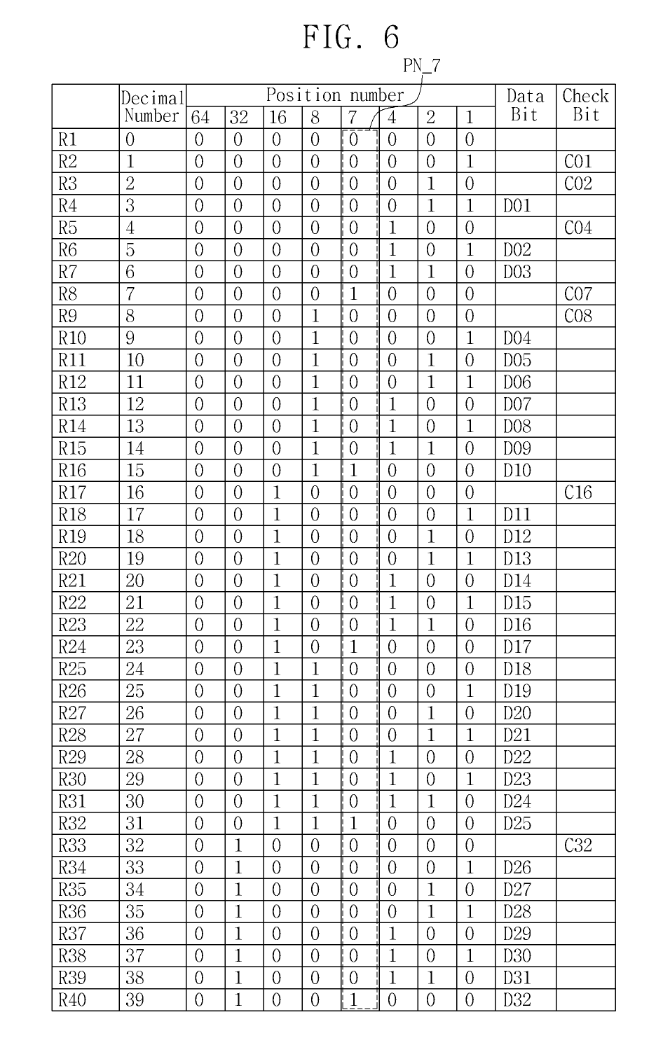

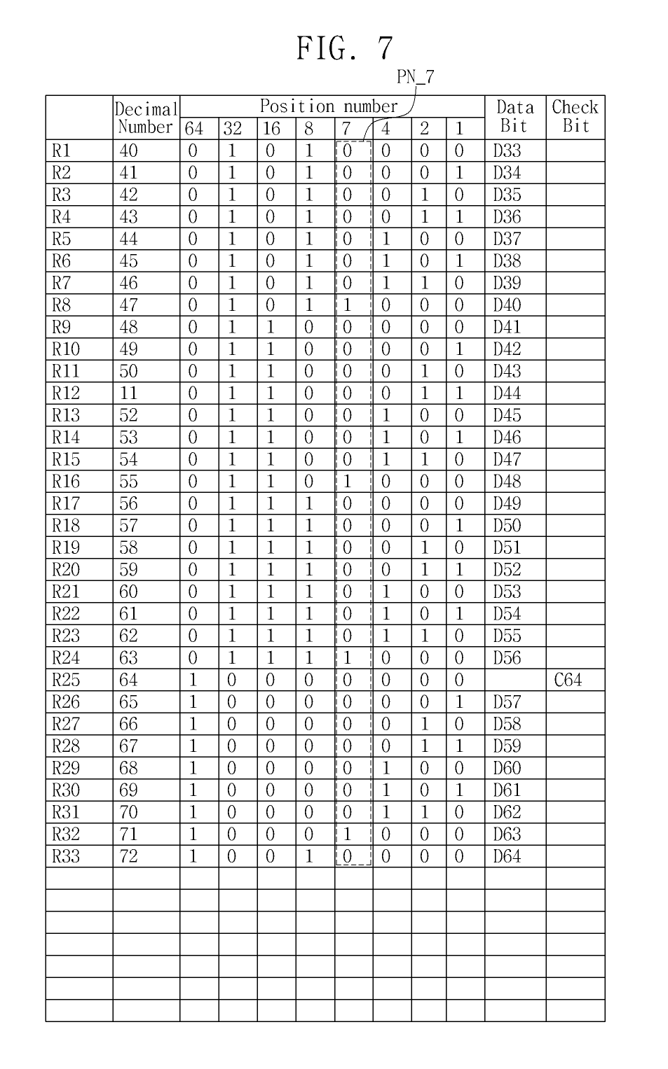

FIGS. 6 and Tare tables rewritten by adding a position number 7 to the tables shown in FIGS. 2 and 3. FIGS. 6 and 7 illustrate a method of disposing check bits and data bits according to position numbers when input data DIN input to the semiconductor memory device 100 is 64 bits.

Referring to FIGS. 6 and 7, position numbers may include not only position numbers based on a binary number system but also an additional position number 7. That is, the position numbers may include a combination of position numbers which are defined as normal position numbers and those which are not, for example 1, 2, 4, 7, 8, 16, 32, and 64. In FIGS. 2 and 3, when each of the position numbers 1, 2, and 4 has the value “1”, the value of each of the position numbers 1, 2, and 4 may be replaced by a value “0”, and “1” may be written in a position of the additional position number 7, thereby preparing a space PN_{—}7 of the additional position number 7 of FIGS. 6 and 7.

Accordingly, check bits according to embodiments of the inventive concepts may further include new check bits having common elements that may construct conventional functions of check bits, in addition to check bits obtained based on conventional hamming codes.

Similarly, syndrome bits according to embodiments of the inventive concepts may further include new syndrome bits having common elements that may construct conventional functions of syndrome bits, in addition to syndrome bits obtained based on conventional hamming codes.

In the above-described example, the check bit C01 may be disposed in a space where the position number 1 has the value “1”, the check bit C02 may be disposed in a space where the position number 2 has the value “1”, and the check bit C04 may be disposed in a space where the position number 4 has the value “1”. The additional check bit C07 may be obtained based on data bits arranged in a space where each of the position numbers 1, 2, and 4 has the value “1”. Accordingly, a check bit generator configured to generate the check bits C01, C02, and C04 using input data according to embodiments of the inventive concepts may be simpler than a conventional circuit. For instance, the check bit generator according to the embodiments of the inventive concepts may require a smaller number of gates and include smaller numbers of stages and fan-ins than the conventional circuit.

Similarly, the syndrome bit S01 may be disposed in a space where the position number 1 has the value “1”, the syndrome bit S02 may be disposed in a space where the position number 2 has the value “1”, and the syndrome bit S04 may be disposed in a space where the position number 4 has the value “1”. The additional syndrome bit S07 may be obtained based on the data bits arranged in a space where each of the position numbers 1, 2, and 4 has the value “1”. Accordingly, a syndrome bit generating circuit configured to generate the syndrome bits S01, S02, and S04 using input data according to embodiments of the inventive concepts may be simpler than a conventional circuit. For instance, the syndrome bit generating circuit according to the embodiments of the inventive concepts may require a smaller number of gates and include smaller numbers of stages and fan-ins than the conventional circuit.

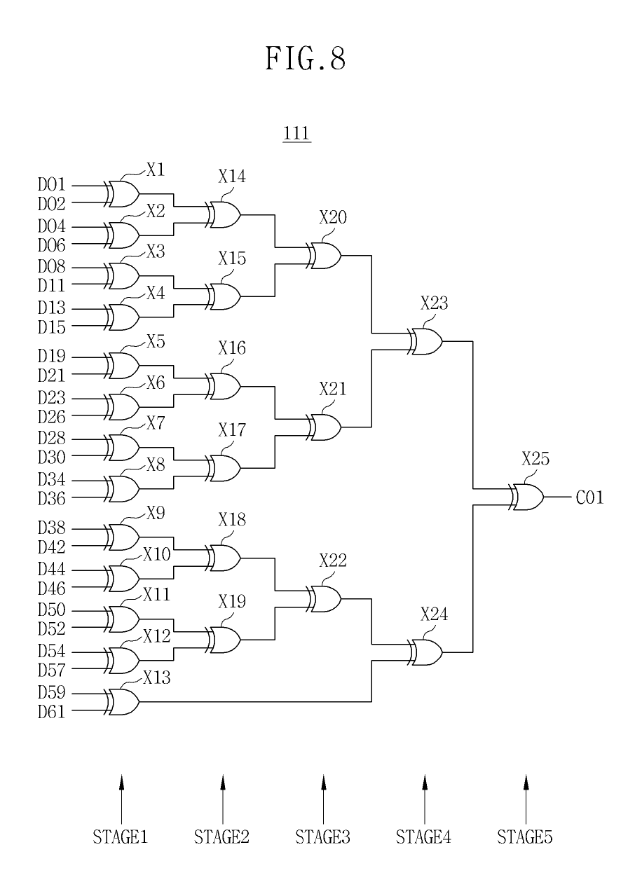

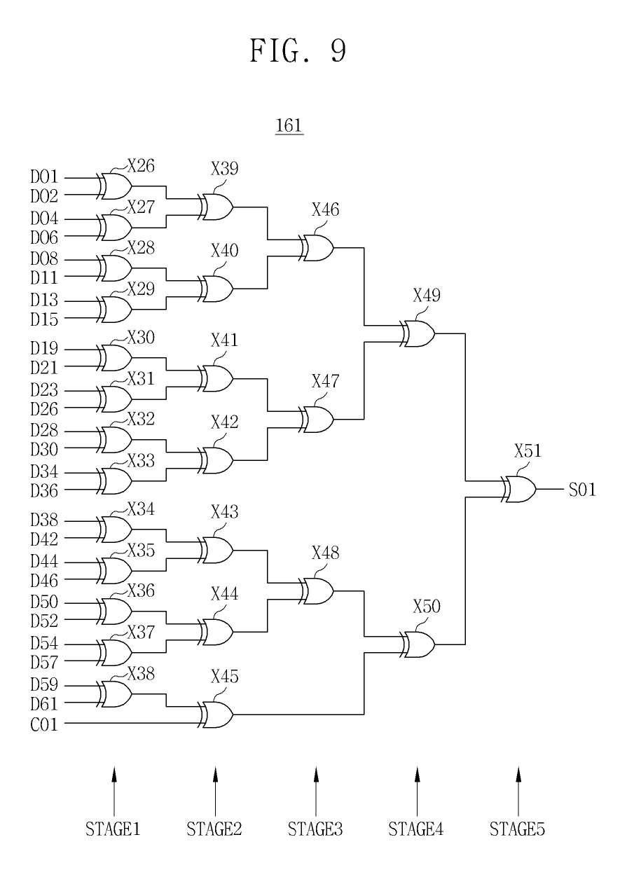

FIGS. 8 and 9 are, respectively, circuit diagrams of circuits 111 and 161 configured to generate a check bit C01 shown in FIG. 4 and a syndrome bit S01 shown in FIG. 5 using a plurality of XOR gates.

Referring to FIG. 8, the circuit 111 configured to the check bit C01 may include XOR gates X1 to X25, and five stages STAGE1, STAGE2, STAGE3, STAGE4, and STAGE5. The circuit 111 configured to generate the check bit C01 may generate the check C01 using data bits D01, D02, D04, D06, D08, D11, D13, D15, D19, D21, D23, D26, D28, D30, D34, D36, D38, D42, D44, D46, D50, D52, D54, D57, D59, and D61.

Referring to FIG. 9, the circuit 161 configured to generate the syndrome bit S01 may include XOR gates X26 to X51, and five stages STAGE1, STAGE2, STAGE3, STAGE4, and STAGE5. The circuit 161 configured to generate the syndrome bit S01 may generate the syndrome bit S01 using the data bits D01, D02, D04, D06, D08, D11, D13, D15, D19, D21, D23, D26, D28, D30, D34, D36, D38, D42, D44, D46, D50, D52, D54, D57, D59, and D61, and the check bit C01.

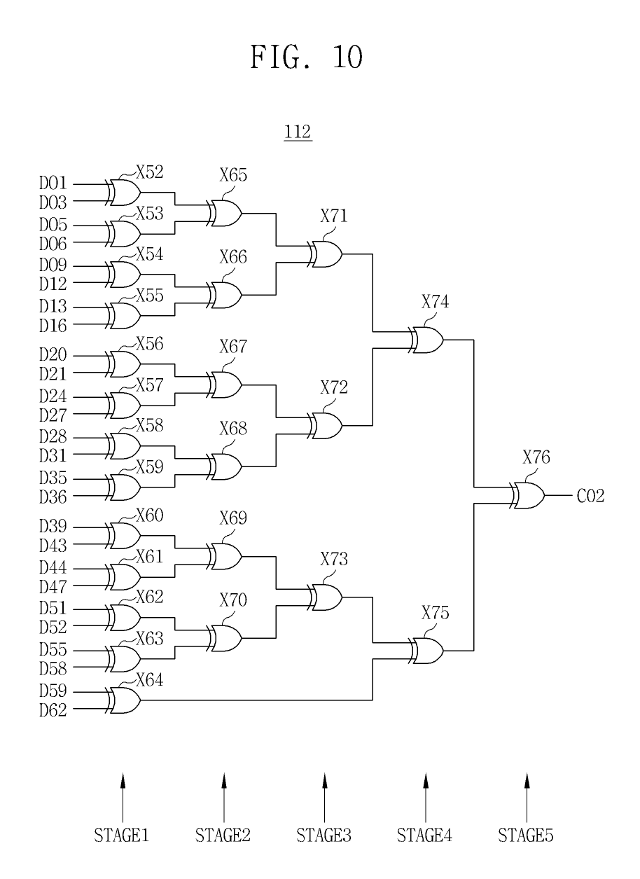

FIGS. 10 and 11 are, respectively, circuit diagrams of circuits 112 and 162 configured to generate a check bit C02 and a syndrome bit S02 shown in FIG. 5 using a plurality of XOR gates.

Referring to FIG. 10, the circuit 112 configured to generate the check bit C02 may include XOR gates X52 to X76, and five stages STAGE1, STAGE2, STAGE3, STAGE4, and STAGE5. The circuit 112 configured to generate the check bit C02 may generate the check bit C02 using the data bits D01, D03, D05, D06, D09, D12, D13, D16, D20, D21, D24, D27, D28, D31, D35, D36, D39, D43, D44, D47, D51, D52, D55, D58, D59, and D62.

Referring to FIG. 11, the circuit 162 configured to generate a syndrome bit S02 may include XOR gates X77 to X102, and five stages STAGE1, STAGE2, STAGE3, STAGE4, and STAGE5. The circuit 162 configured to generate the syndrome bit S02 may generate the syndrome bit S02 using the data bits D01, D03, D05, D06, D09, D12, D13, D16, D20, D21, D24, D27, D28, D31, D35, D36, D39, D43, D44, D47, D51, D52, D55, D58, D59, and D62, and the check bit C02.

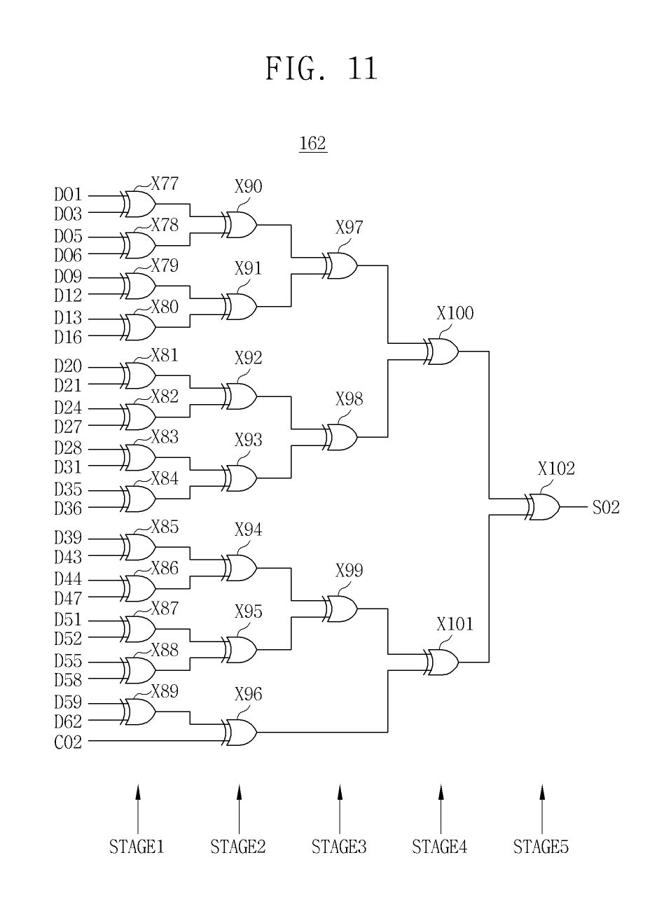

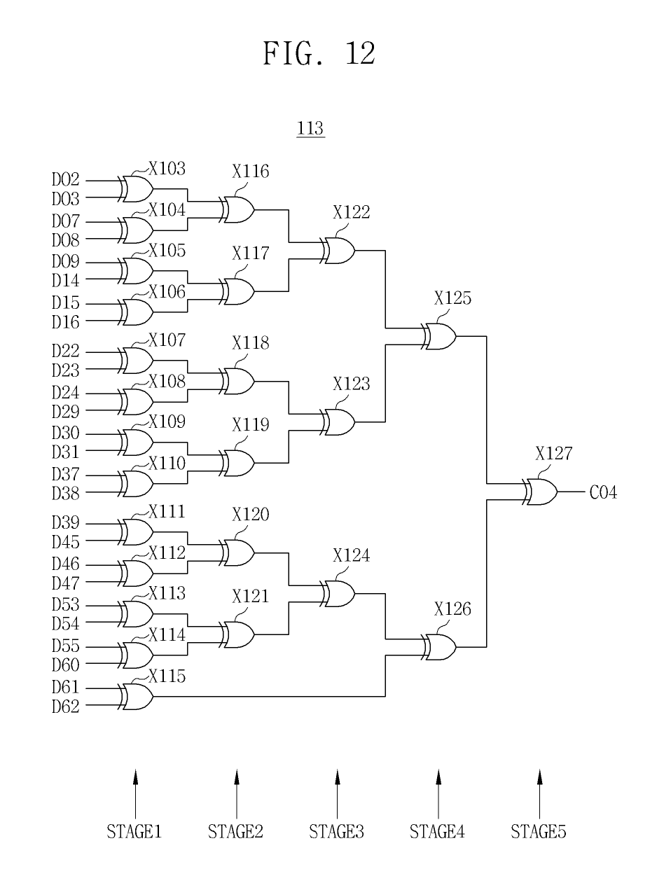

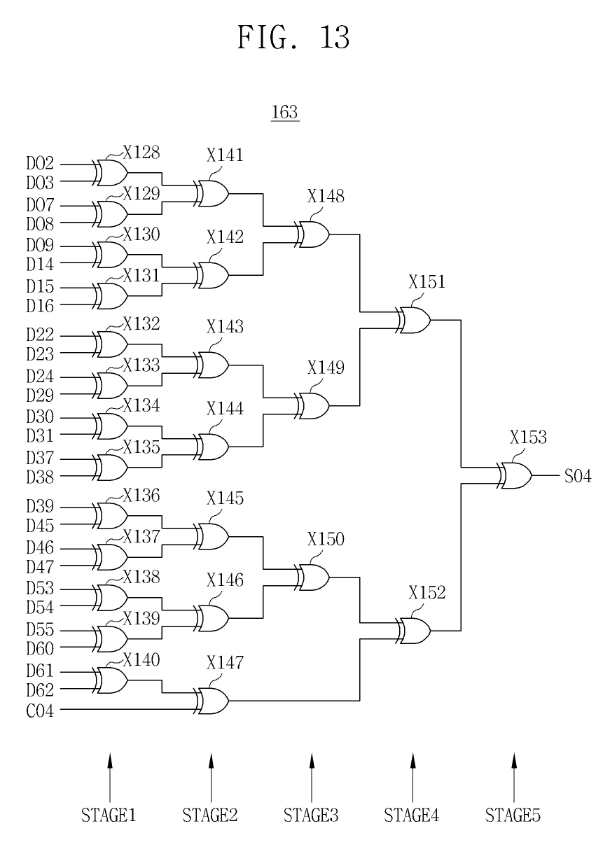

FIGS. 12 and 13 are, respectively, circuit diagrams of circuits 113 and 163 configured to generate a check bit C04 shown in FIG. 4 and a syndrome bit S04 shown in FIG. 5 using a plurality of XOR gates.

Referring to FIG. 12, the circuit 113 configured to generate the check bit C04 may include OR gates X103 to X127, and five stages STAGE1, STAGE2, STAGE3, STAGE4, and STAGE5. The circuit 113 configured to generate the check bit C04 may generate the check bit C04 using the data bits D02, D03, D07, D08, D09, D14, D15, D16, D22, D23, D24, D29, D30, D31, D37, D38, D39, D45, D46, D47, D53, D54, D55, D60, D61, and D62.

Referring to FIG. 13, the circuit 163 configured to generate the syndrome bit S04 may include OR gates X128 to X153, and five stages STAGE1, STAGE2, STAGE3, STAGE4, and STAGE5. The circuit 163 configured to generate the syndrome bit S04 may generate the syndrome bit S04 using the data bits D02, D03, D07, D08, D09, D14, D15, D16, D22, D23, D24, D29, D30, D31, D37, D38, D39, D45, D46, D47, D53, D54, D55, D60, D61, and D62, and the check bit C04.

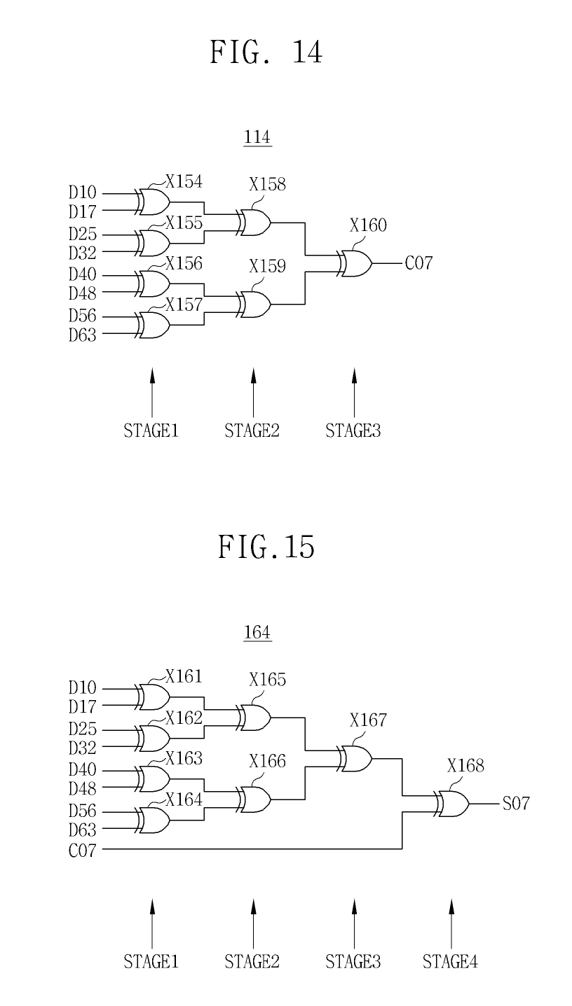

FIGS. 14 and 15 are, respectively, circuit diagrams of circuits 114 and 164 configured to generate a check bit C07 shown in FIG. 4 and a syndrome bit S07 shown in FIG. 5 using a plurality of XOR gates.

Referring to FIG. 14, the circuit 114 configured to generate the check bit C07 may include OR gates X154 to X160, and three stages STAGE1, STAGE2, and STAGE3. The circuit 114 configured to generate the check bit C07 may generate the check bit C07 using the data bits D10, D17, D25, D32, D40, D48, D56, and D63.

Referring to FIG. 15, the circuit 164 configured to generate the syndrome bit S07 may include XOR gates X161 to X168, and four stages STAGE1, STAGE2, STAGE3, and STAGE4. The circuit 164 configured to generate the syndrome bit S07 may generate the syndrome bit S07 using the data bits D10, D17, D25, D32, D40, D48, D56, and D63, and the check bit C07.

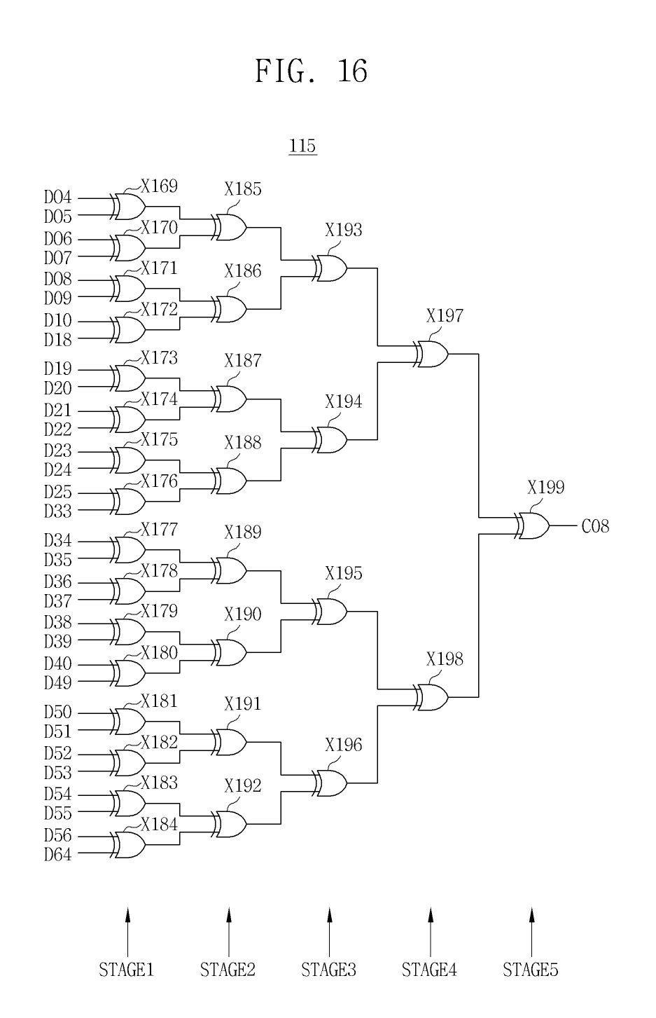

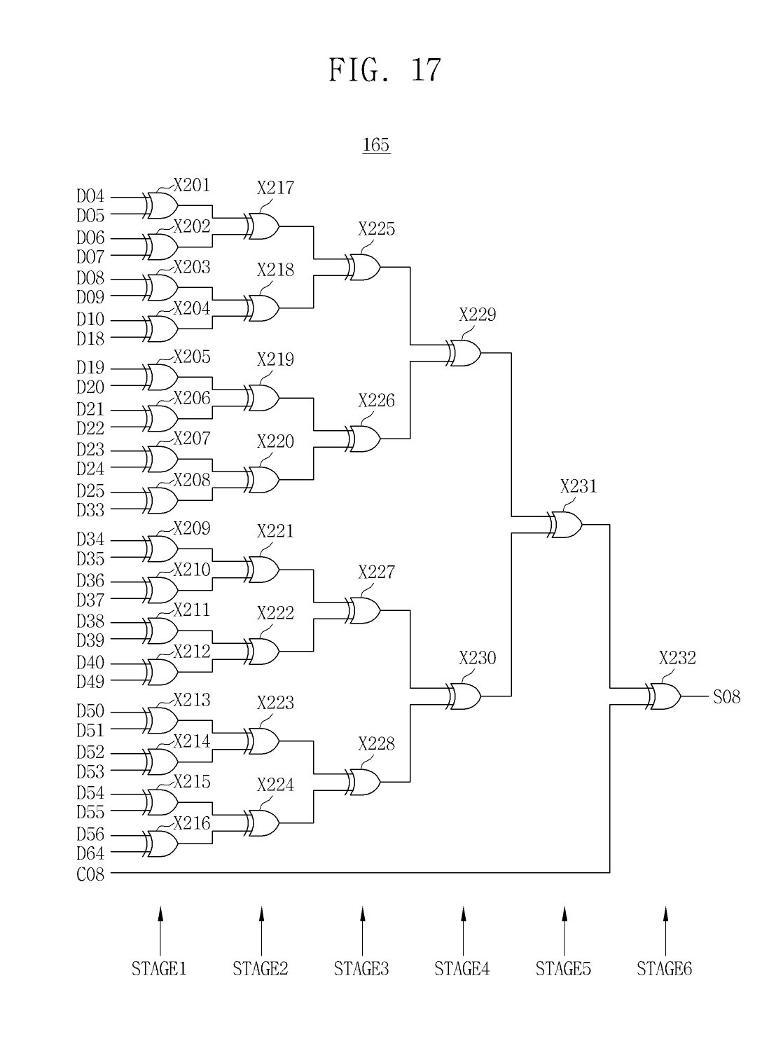

FIGS. 16 and 17 are, respectively, circuit diagrams of circuits 115 and 165 configured to generate a check bit C08 and a syndrome bit C08 shown in FIG. 5 using a plurality of XOR gates.

Referring to FIG. 16, the circuit 115 configured to generate the check bit C08 may include XOR gates X169 to X199, and five stages STAGE1, STAGE2, STAGE3, STAGE4, and STAGE5. The circuit 115 configured to generate the check bit C08 may generate the check bit C08 using the data bits D04, D05, D06, D07, D08, D09, D10, D18, D19, D20, D21, D22, D23, D24, D25, D33, D34, D35, D36, D37, D38, D39, D40, D49, D50, D51, D52, D53, D54, D55, D56, and D64.

Referring to FIG. 17, the circuit 165 configured to generate the syndrome bit S08 may include XOR gates X201 to X232, and six stages STAGE1, STAGE2, STAGE3, STAGE4, STAGE5, and STAGE6. The circuit 165 configured to generate the syndrome bit S08 may generate the syndrome bit S08 using the data bits D04, D05, D06, D07, D08, D09, D10, D18, D19, D20, D21, D22, D23, D24, D25, D33, D34, D35, D36, D37, D38, D39, D40, D49, D50, D51, D52, D53, D54, D55, D56, and D64, and the check bit C08.

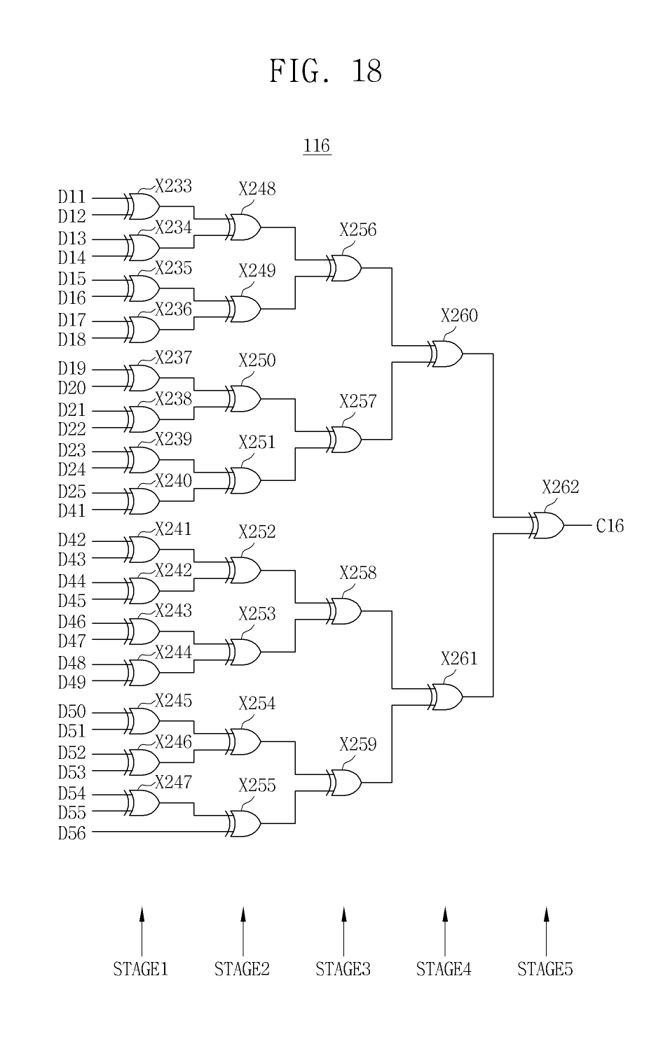

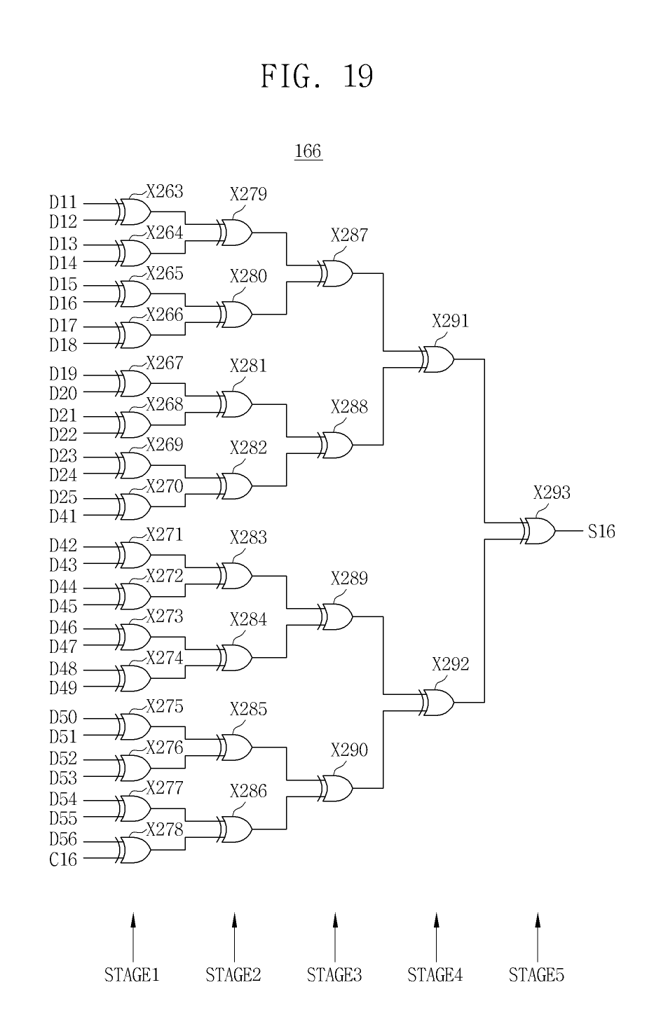

FIGS. 18 and 19 are, respectively, circuit diagrams of circuits 116 and 166 configured to generate a check bit C16 shown in FIG. 4 and a syndrome bit S16 shown in FIG. 5 using a plurality of XOR gates.

Referring to FIG. 18, the circuit 116 configured to generate the check bit C16 may include XOR gates X233 to X262, and five stages STAGE1, STAGE2, STAGE3, STAGE4, and STAGE5. The circuit 116 configured to generate the check bit C16 may generate the check bit C16 using the data bits D11, D12, D13, D14, D15, D16, D17, D18, D19, D20, D21, D22, D23, D24, D25, D41, D42, D43, D44, D45, D46, D47, D48, D49, D50, D51, D52, D53, D54, D55, and D56.

Referring to FIG. 19, the circuit 166 configured to generate the syndrome bit S16 may include XOR gates X263 to X293, and five stages STAGE1, STAGE2, STAGE3, STAGE4, and STAGE5. The circuit 166 configured to generate the syndrome bit S 16 may generate the syndrome bit S16 using the data bits D11, D12, D13, D14, D15, D16, D17, D18, D19, D20, D21, D22, D23, D24, D25, D41, D42, D43, D44, D45, D46, D47, D48, D49, D50, D51, D52, D53, D54, D55, and D56, and the check bit C16.

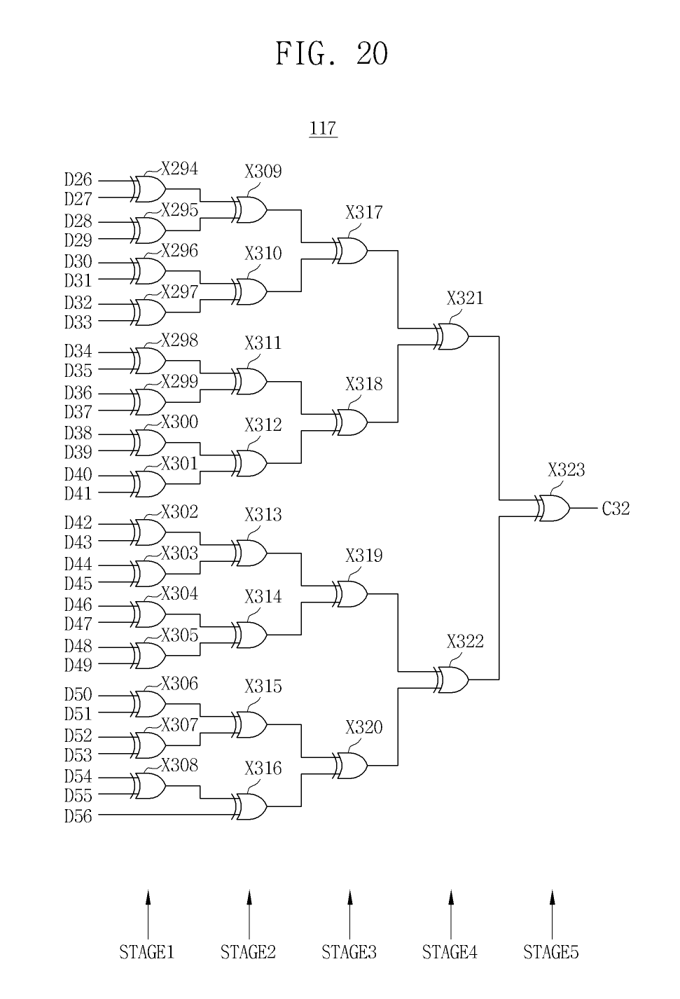

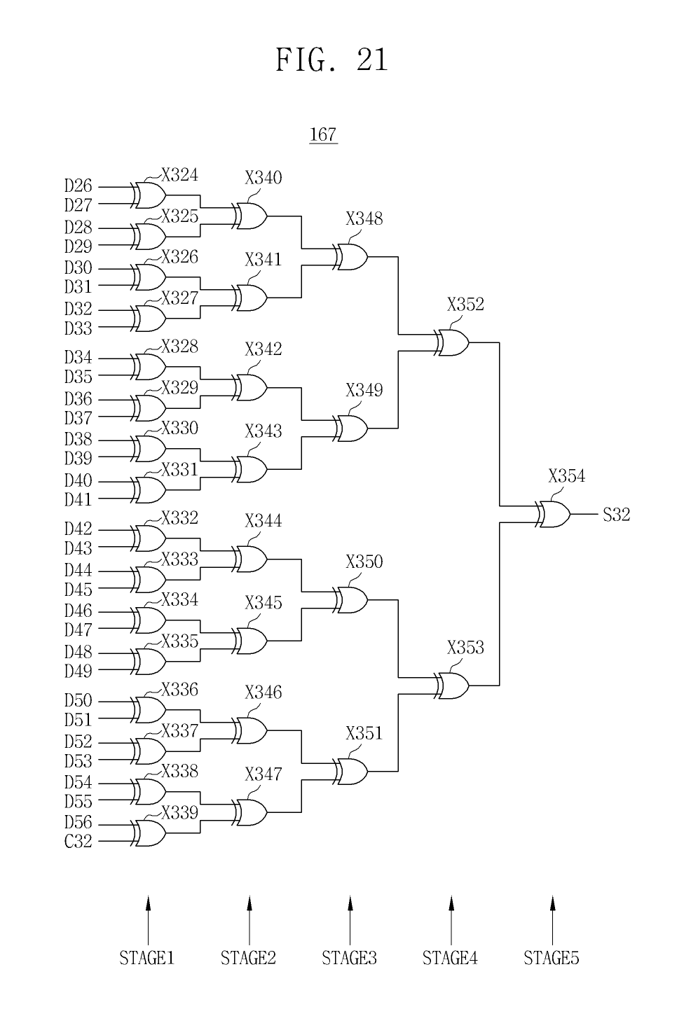

FIGS. 20 and 21 are, respectively, circuit diagrams of circuits 117 and 167 configured to generate a check bit C32 and a syndrome bit S32 shown in FIG. 5 using a plurality of XOR gates.

Referring to FIG. 20, the circuit 117 configured to generate the check bit C32 may include XOR gates X294 to X323, and five stages STAGE1, STAGE2, STAGE3, STAGE4, and STAGE5. The circuit 117 configured to generate the check bit C32 may generate the check bit C32 using the data bits D26, D27, D28, D29, D30, D31, D32, D33, D34, D35, D36, D37, D38, D39, D40, D41, D42, D43, D44, D45, D46, D47, D48, D49, D50, D51, D52, D53, D54, D55, and D56.

Referring to FIG. 21, the circuit 167 configured to generate the syndrome bit S32 may include XOR gates X324 to X354, and five stages STAGE1, STAGE2, STAGE3, STAGE4, and STAGE5. The circuit 167 configured to generate the syndrome bit S32 may generate the syndrome bit S32 using the data bits D26, D27, D28, D29, D30, D31, D32, D33, D34, D35, D36, D37, D38, D39, D40, D41, D42, D43, D44, D45, D46, D47, D48, D49, D50, D51, D52, D53, D54, D55, and D56, and the check bit C32.

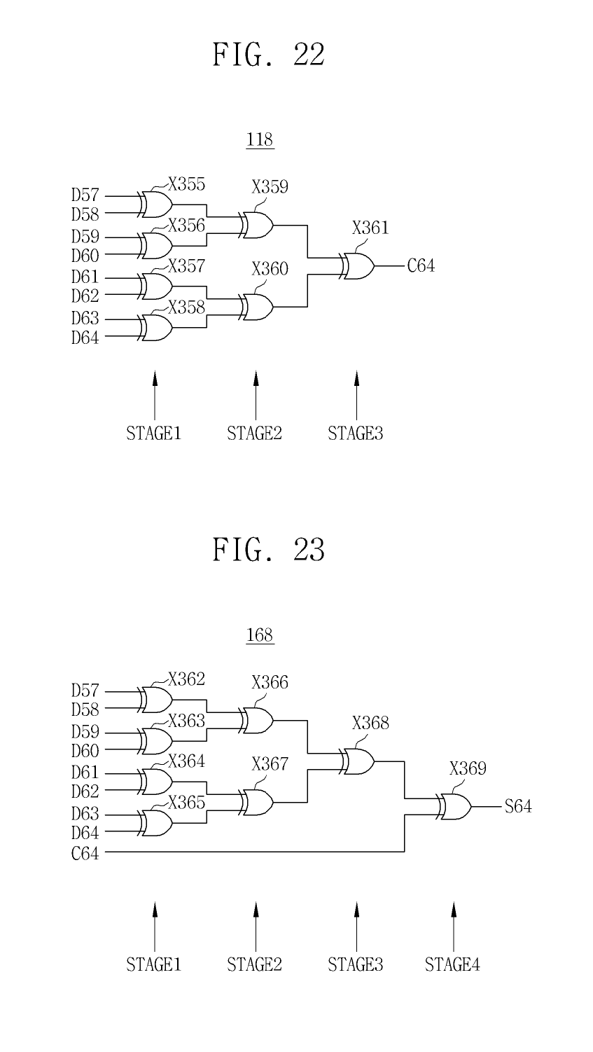

FIGS. 22 and 23 are, respectively, circuit diagrams of circuits 118 and 168 configured to generate a check bit C64 and a syndrome bit S64 shown in FIG. 5 using a plurality of XOR gates.

Referring to FIG. 22, the circuit 118 configured to generate the check bit C64 may include XOR gates X355 to X361, and three stages STAGE1, STAGE2, and STAGE3. The circuit 118 configured to generate the check bit C64 may generate the check bit C64 using the data bits D57, D58, D59, D60, D61, D62, D63, and D64.

Referring to FIG. 23, the circuit 168 configured to generate the syndrome bit S64 may include XOR gates X362 to X369, and four stages STAGE1, STAGE2, STAGE3, and STAGE4. The circuit 168 configured to generate the syndrome bit S64 may generate the syndrome bit S64 using the data bits D57, D58, D59, D60, D61, D62, D63, and D64, and the check bits C64.

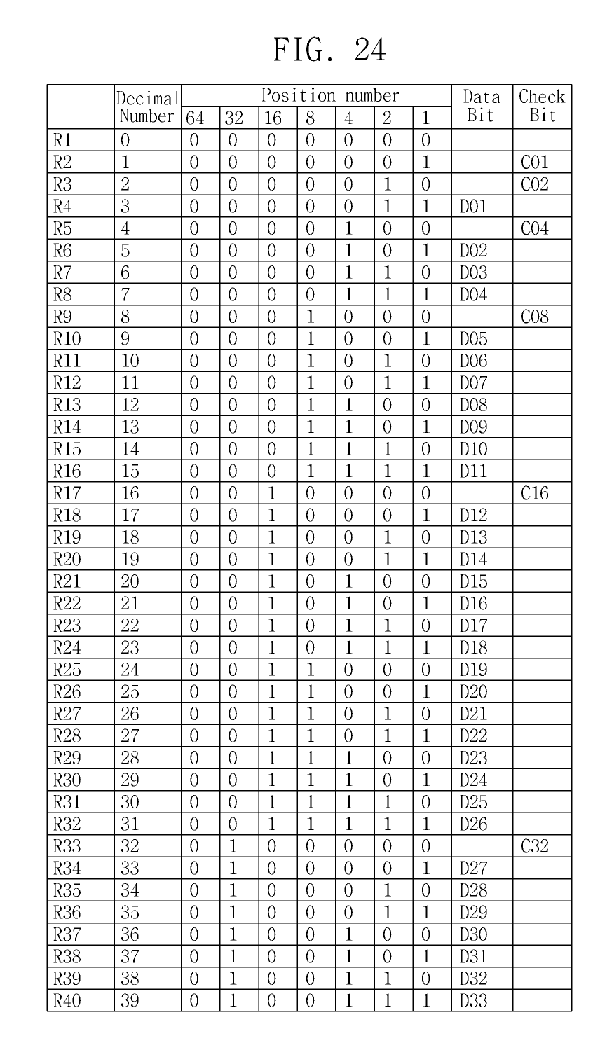

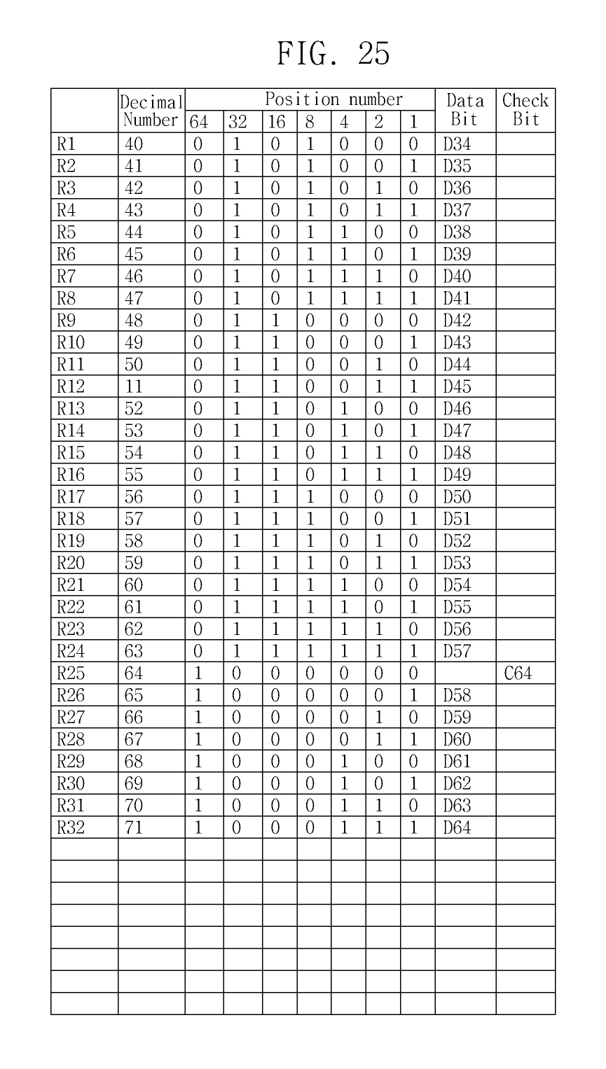

FIGS. 24 and 25 are tables showing an example of a method of disposing check bits and data bits used in a conventional semiconductor memory device according to position numbers.

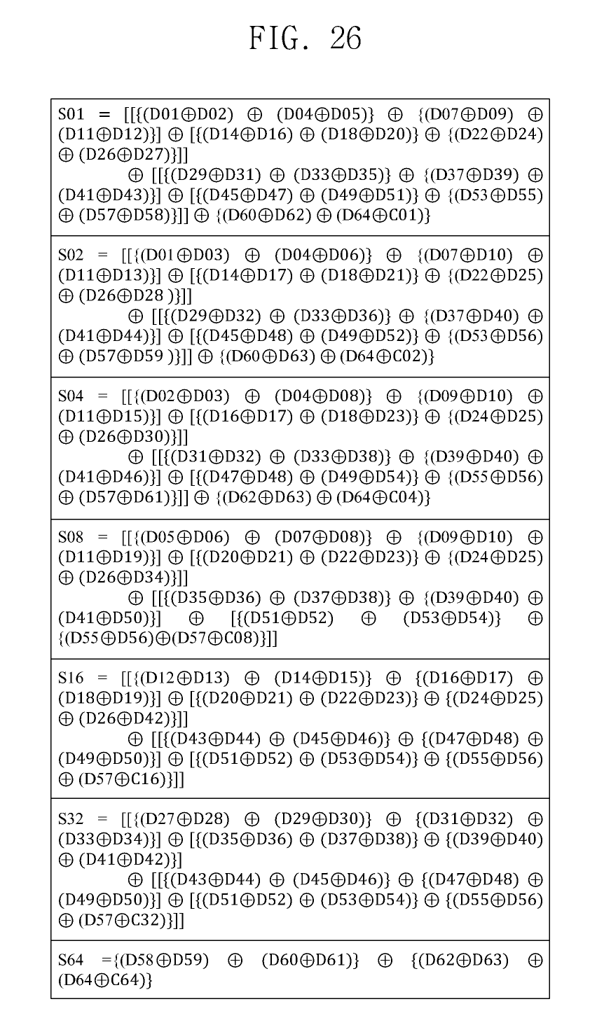

FIG. 26 is a table showing an example of a method of generating check bits using the data bits shown in FIGS. 24 and 25, and FIG. 27 is a circuit diagram of a circuit configured to generate a syndrome bit S01 shown in the table of FIG. 26 using a plurality of XOR gates.

Referring to FIGS. 24 through 27, a conventional method of generating check bits and syndrome bits may be different from a method of generating check bits and syndrome bits according to embodiments of the inventive concepts.

Referring to FIGS. 24 and 25, in a conventional method of disposing check bits and data bits according to position numbers, check bits may be disposed in positions corresponding to position numbers including only binary position numbers, namely, 1, 2, 4, 8, 16, 32, and 64, while a check bit may not be disposed in a position corresponding to a position number 7, that is, a position corresponding to“0000111”. Instead, data D04 may be conventionally disposed in a position corresponding to “0000111”.

Referring to FIG. 26, a conventional function for generating syndrome bits, namely, a logic expression for generating syndrome bits may be more complicated than the logic expression shown in FIG. 5 according to embodiments of the inventive concepts. For example, logic expressions of syndrome bits S01, S02, and S04 may be more complicated than logic expressions of syndrome bits S01, S02, and S04 according to embodiments of the inventive concepts.

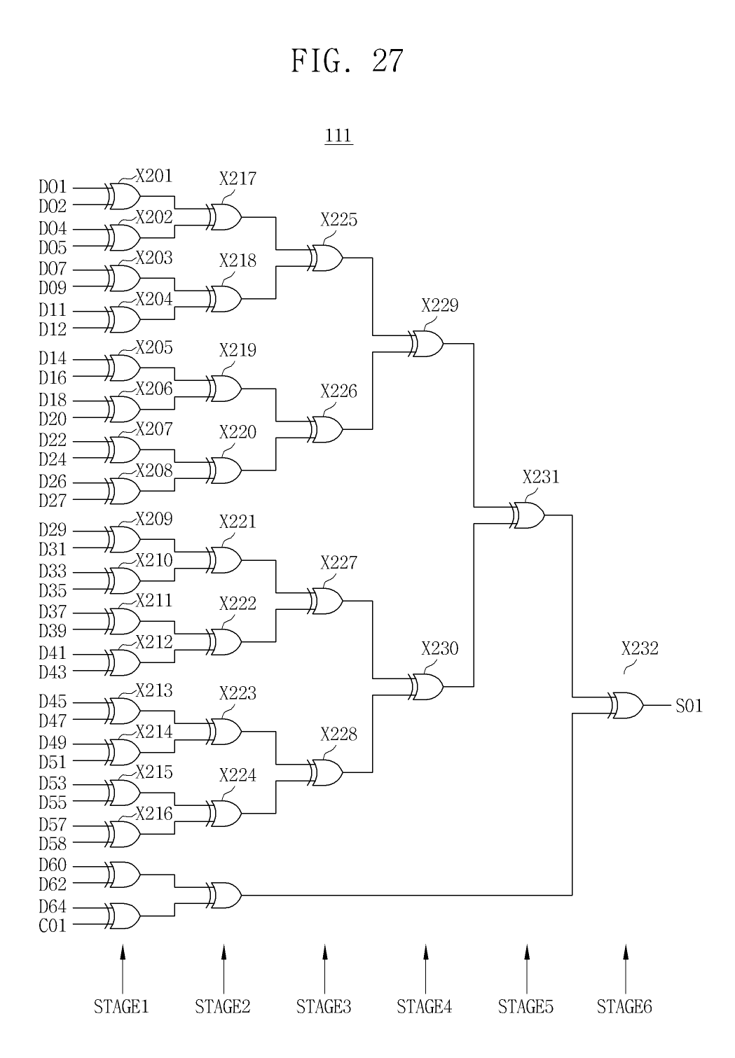

Referring to FIG. 27, a conventional circuit configured to generate a syndrome bit S01 may have 35 XOR gates, receive 35 input data and a check bit C01, and include 6 circuit stages STAGE1, STAGE2, STAGE3, STAGE4, STAGE5, and STAGE6.

Referring back to FIG. 9, the circuit 161 configured to generate the syndrome bit S01 according to embodiments of the inventive concepts may have 26 XOR gates, receive 26 input data and a check bit C01, and include the five circuit stages STAGE1, STAGE2, STAGE3, STAGE4, STAGE5, and STAGE6. Similarly, as described above, each of the circuits 162 and 163 configured to respectively generate the syndrome bits S02 and S04 may have smaller numbers of gates, circuit stages, and fan-ins than conventional circuits.

In a semiconductor memory device that operates in a pre-fetch (2 bits or more) mode, there may be cases where the orders of input data and output data may be reversed due to the ordering of output data DQ. Accordingly, the semiconductor memory device may output error data.

Check bits obtained during a write operation, and syndrome bits obtained during a read operation should be generated using the same data. However, due to the ordering of data, it may not be easy to generate the syndrome bits using the same data.

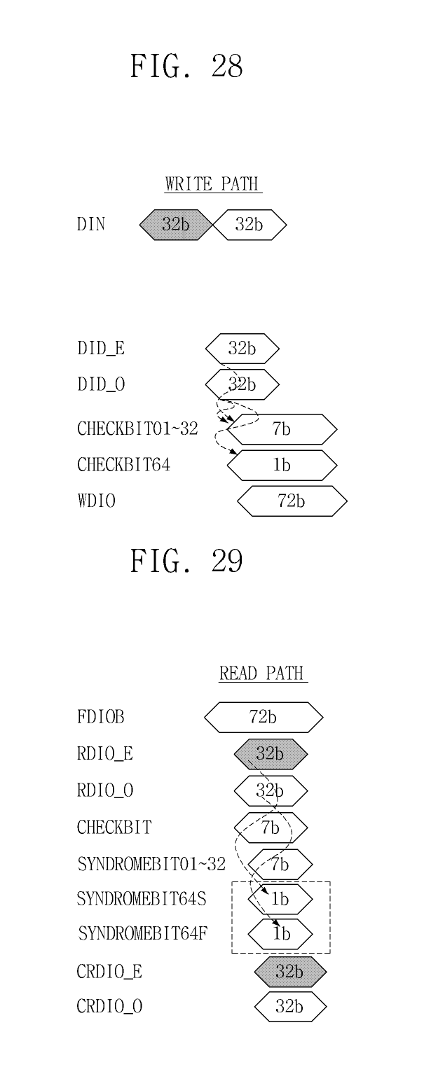

FIG. 28 is a diagram of an example of a data write path of the semiconductor memory device of FIG. 1, and FIG. 29 is a diagram of an example of a data read path of the semiconductor memory device of FIG. 1.

Referring to FIG. 28, among 64-bit input data DIN, 32-bit even data DID_E may be written first, and 32-bit odd data DID_O may then be written. Check bits C01 to C32 and C64 may be generated and stored in the memory cell array 120. 72-bit data including 64-bit data and 8 check bits may be stored. The check bit C64 may be generated using only odd ordering information. Referring to FIG. 29, the semiconductor memory device 100 may read even data RDIO_E, odd data RDIO_O, and check bits CHECKBIT of 72-bit data FDIOB stored in the memory cell array 120, and generate syndrome bits S01 to S32, S64S, and S64F based on the even data RDIO_E, the odd data RDIO_O, and the check bits CHECKBIT. The syndrome bit S64 may be generated in response to each of the even data RDIO_E and the odd data RDIO_O. One of syndrome bits S64S and S64F may be selected using ordering information, and the even data RDIO_E and the odd data RDIO_O may be corrected using the selected syndrome bit S64S or S64F to generate corrected even data CRDIO_E and odd data CRDIO_O.

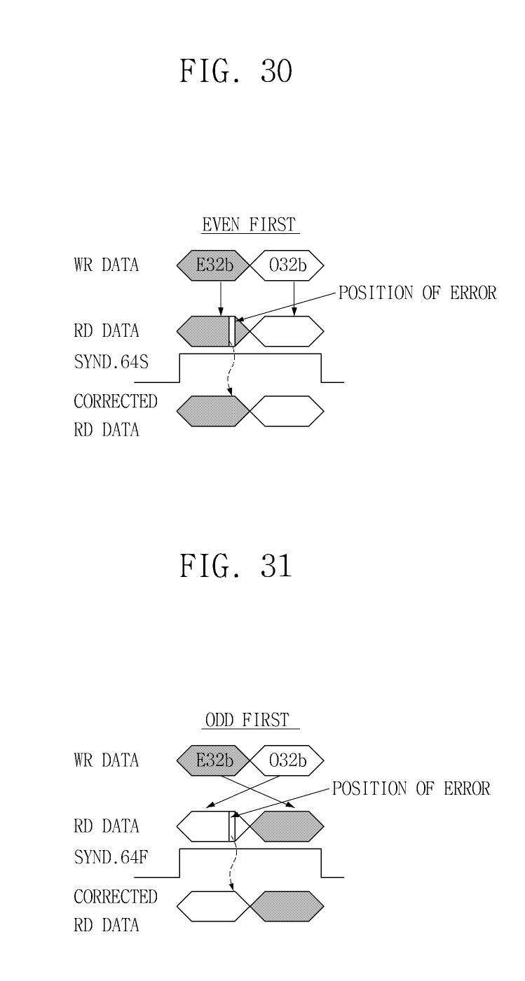

FIG. 30 is a diagram showing a relationship between write data and read data when a semiconductor memory device has an even-first data output structure, and FIG. 31 is a diagram showing a relationship between write data and read data when a semiconductor memory device has an odd-first data output structure.

Referring to FIG. 30, in the case of the even-first input/output (I/O) structure, when data stored in the memory cell array is read, the data may be corrected using the syndrome bit S64S. Referring to FIG. 31, in the case of the odd-first I/O structure, when data stored in the memory cell array is read, the data may be corrected using the syndrome bit S64F.

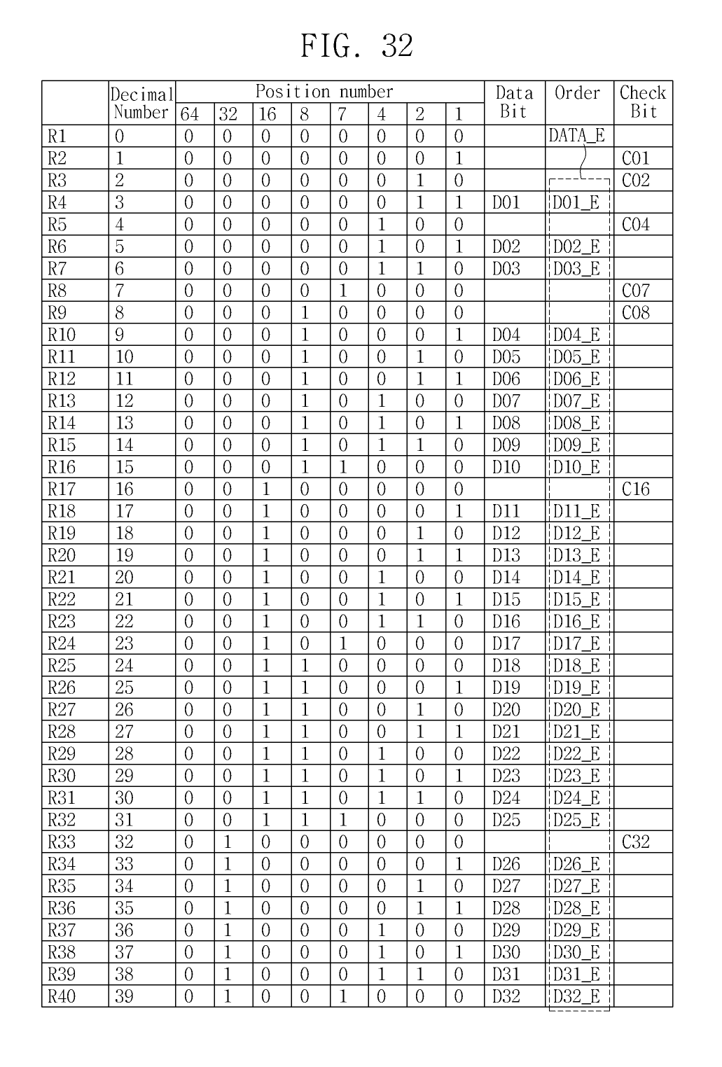

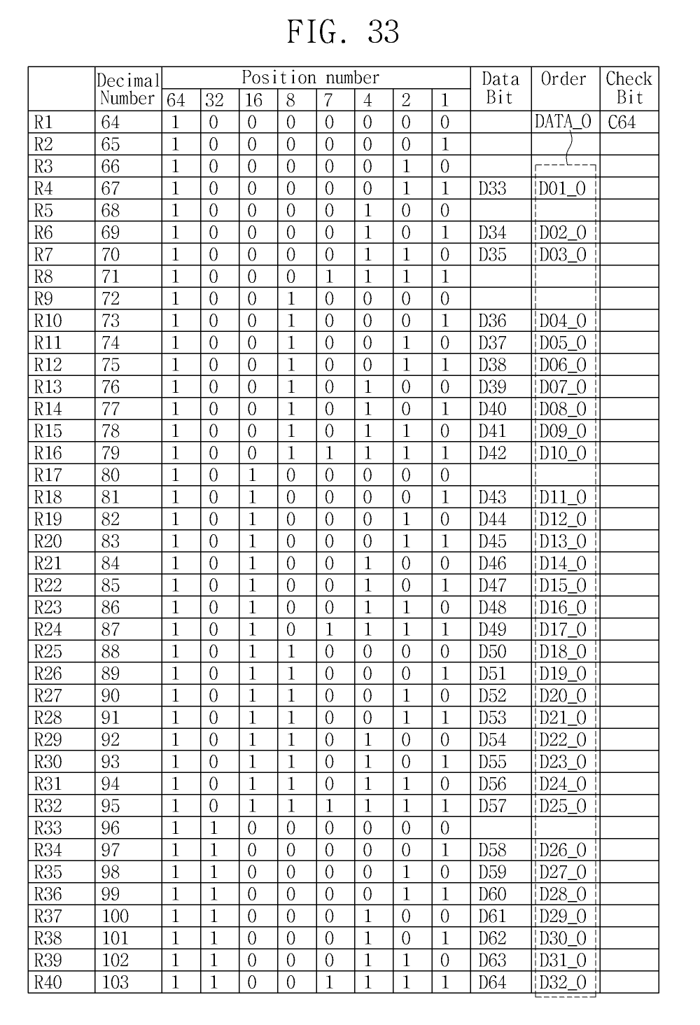

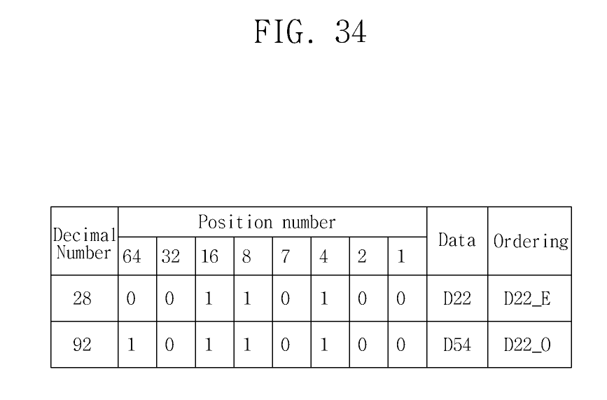

FIGS. 32 and 33 are tables showing an example of disposition of data including data ordering information and check bits in the tables shown in FIGS. 6 and 7; and FIG. 34 is a table showing an example of a method of generating check bits based on ordering information.

When comparing information regarding disposition of input data DIN shown in FIGS. 2 and 3, the same position numbers may be used except for a position number 64. That is, the disposition and use of position numbers 1 through 32 corresponding input data 1 to 32 may be the same as the disposition and use of the position numbers 1 through 32 corresponding to input data 33 to 64, the position number 64 corresponding to only the input data 33 to 64 may be designated, the position number 64 may be combined with data order, and the result may be used to correct errors. A memory device having a 2-bit pre-fetch function may receive data twice consecutively, and store the received data at one time in a cell during a write operation. However, during a subsequent data read operation, since the orders of the data received during the previous write operation may be reversed, the memory device may need to correct the orders of the received data. In this case, an example of a circuit configured to enable an error corrector to use data ordering information is shown in FIGS. 32 and 33. In general, during a read operation, syndrome bits may be obtained using data and check bits, and decoded to confirm and revise error occurrence regions. However, when the circuits are configured as shown in FIGS. 32 and 33, even if the orders of data corresponding to syndrome bits 1 through 32 are reversed, coding differences may not occur. Also, when a syndrome bit 64 is combined with data ordering information and there is no change in data order (assuming that this case is an even-first case), the combined information may be used to code data 33 through 64. When there is a change in data order (assuming that this case is an odd-first case), data may be corrected by coding data 1 through 32 using the syndrome bit 64. For reference, in FIGS. 32 and 33, a change in the order of the input data 1 through 32 and/or a change in the order of the input data 33 through 64 may make no difference. Even and odd data used for the remaining check bits except a check bit 64 may have the same number of bits. Also, syndrome bits may be obtained using the same method as described above.

FIG. 34 is a table for explaining the above description in further detail. Referring to FIG. 34, it can be confirmed that decimal numbers 28 and 92 have the same information except for a position number 64. In FIG. 34, data D22 (even data D22) matches data D54 (odd data D22). When an error corrector is configured, the number of matched combinations may be equal to the number of I/Os of a memory device.

Referring to FIGS. 32 and 33, each of a syndrome bit S64F including only 32-bit even data DATA_E, and a syndrome bit S64S including only 32-bit odd data DATA_O may be generated. Based on ordering information, when the semiconductor memory device has an even-first data I/O structure and outputs data, error data may be corrected using the syndrome bit S64S; while when the semiconductor memory device has an odd-first data I/O structure and outputs data, error data may be corrected using the syndrome bit S64F.

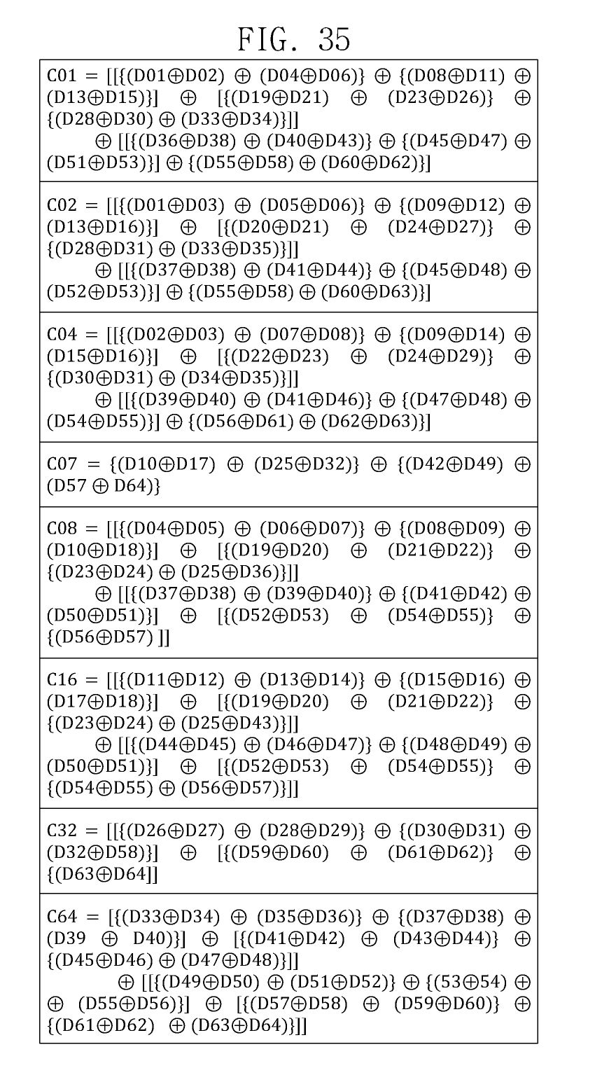

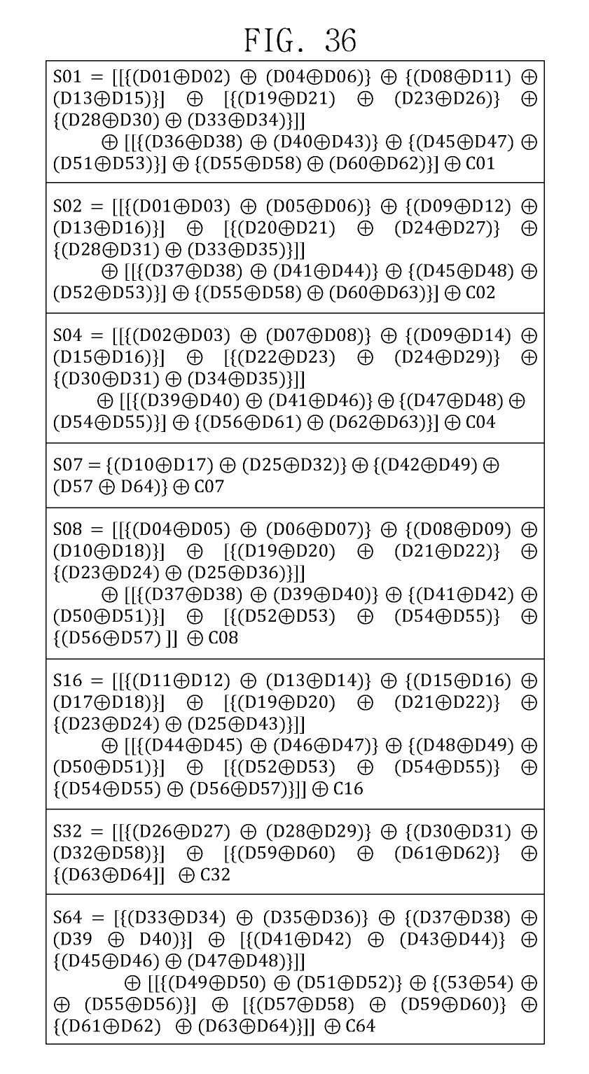

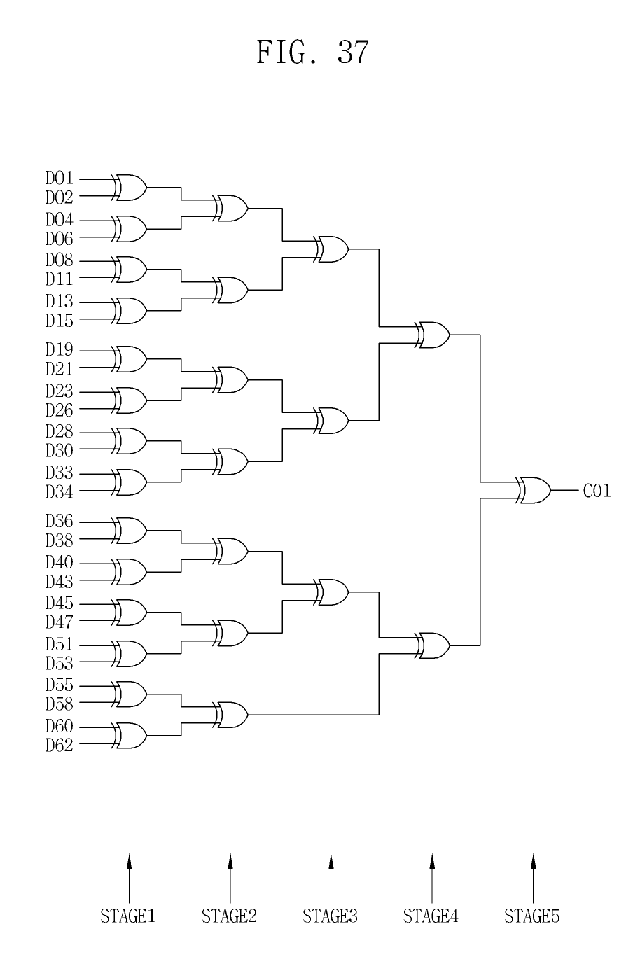

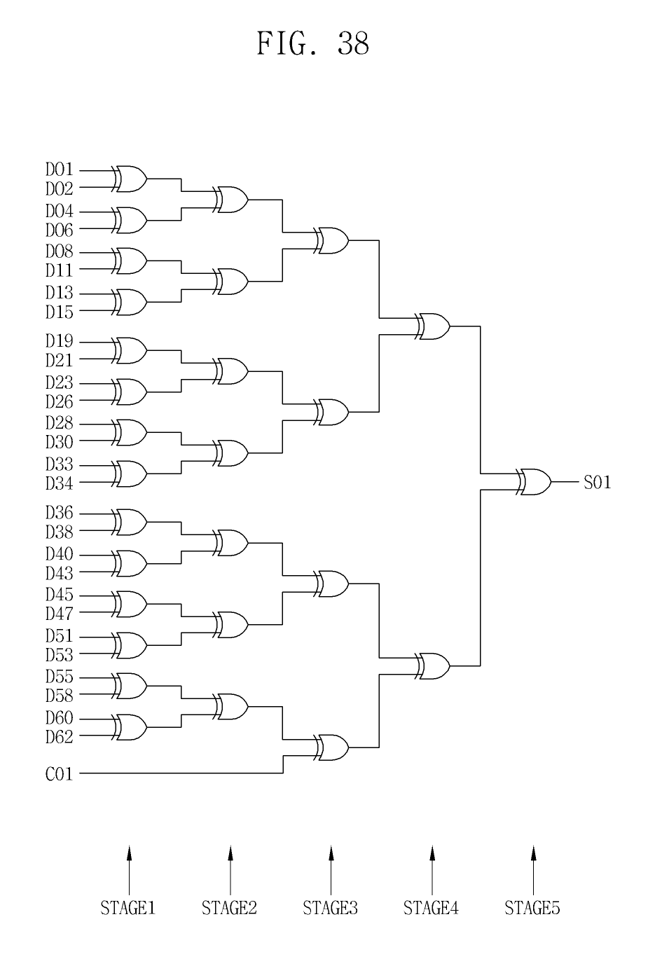

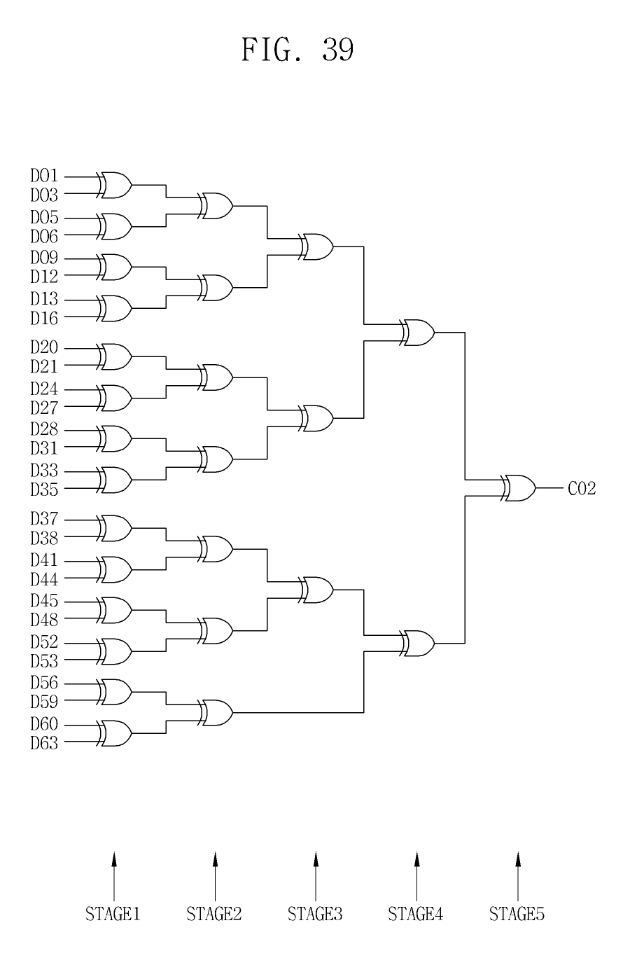

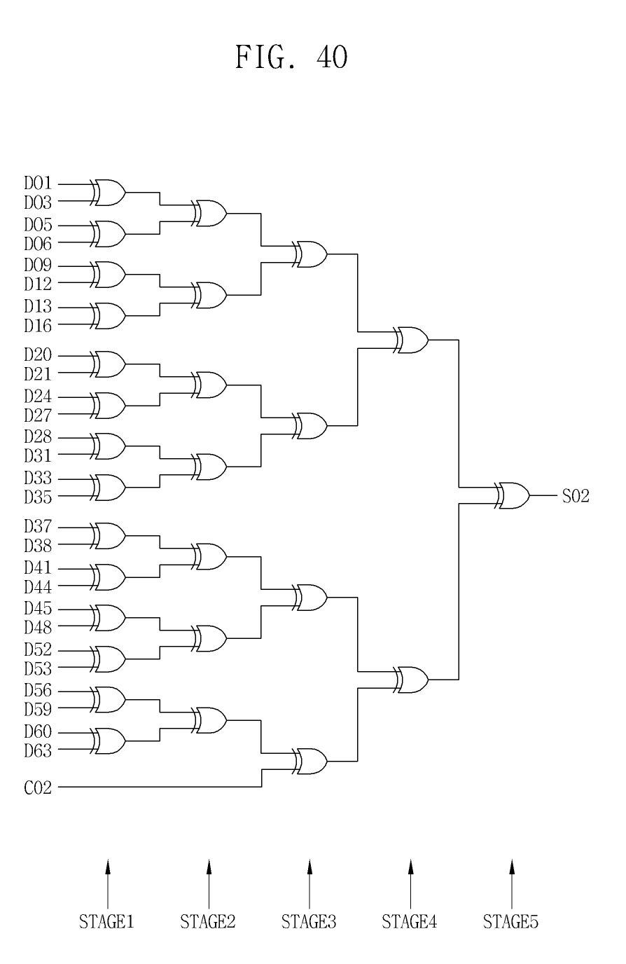

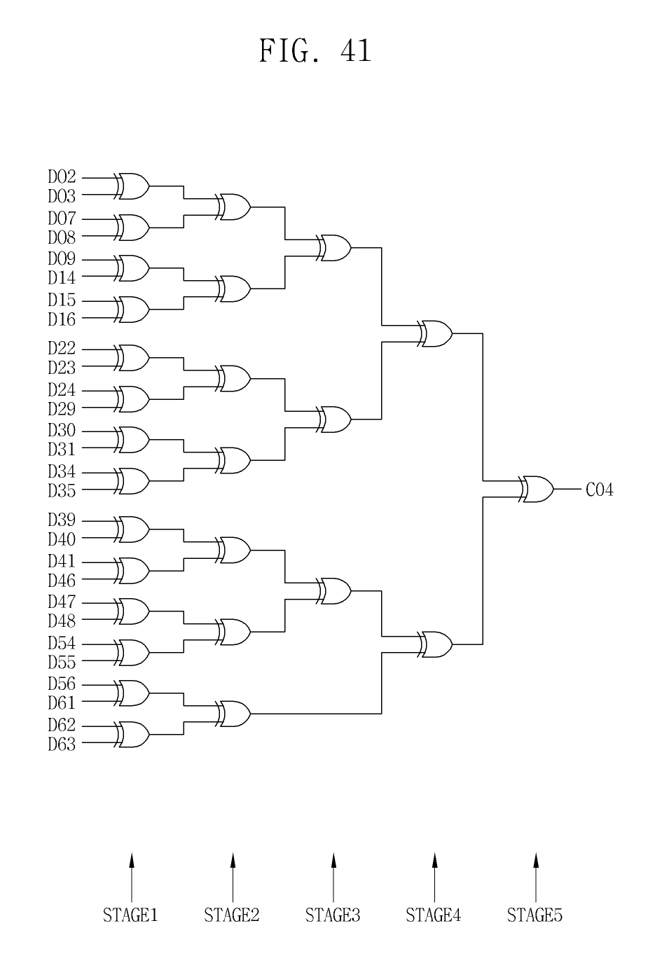

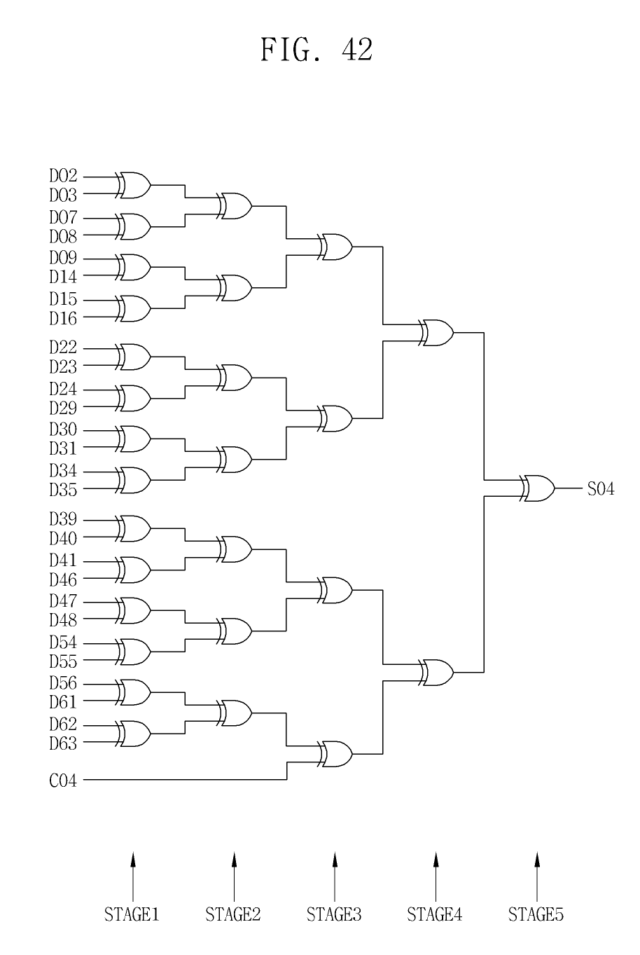

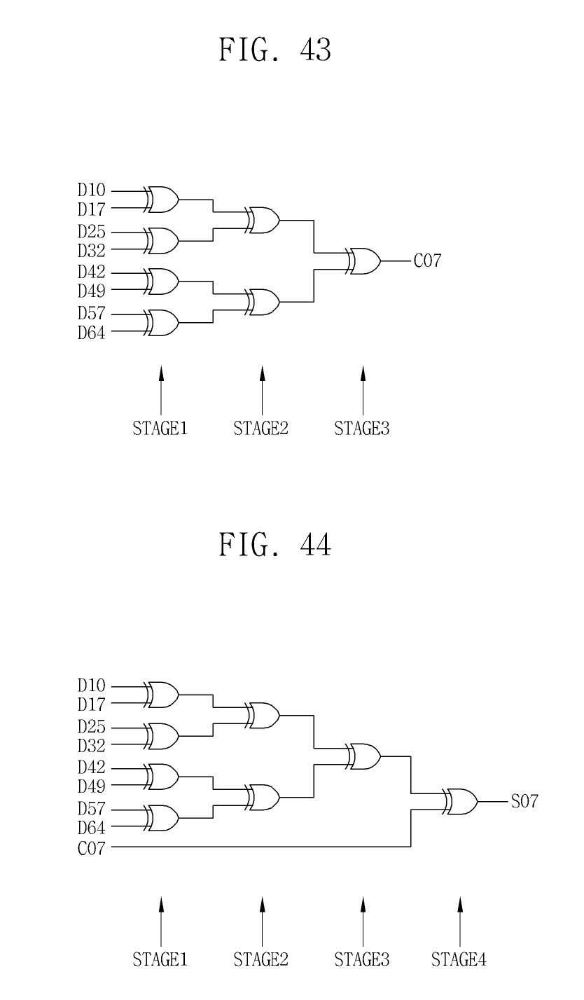

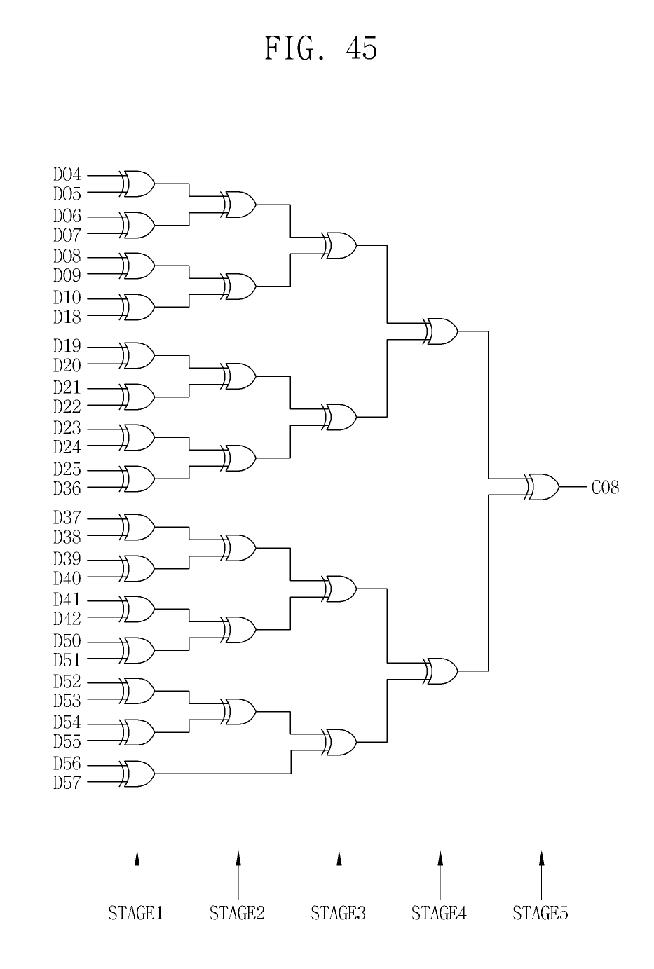

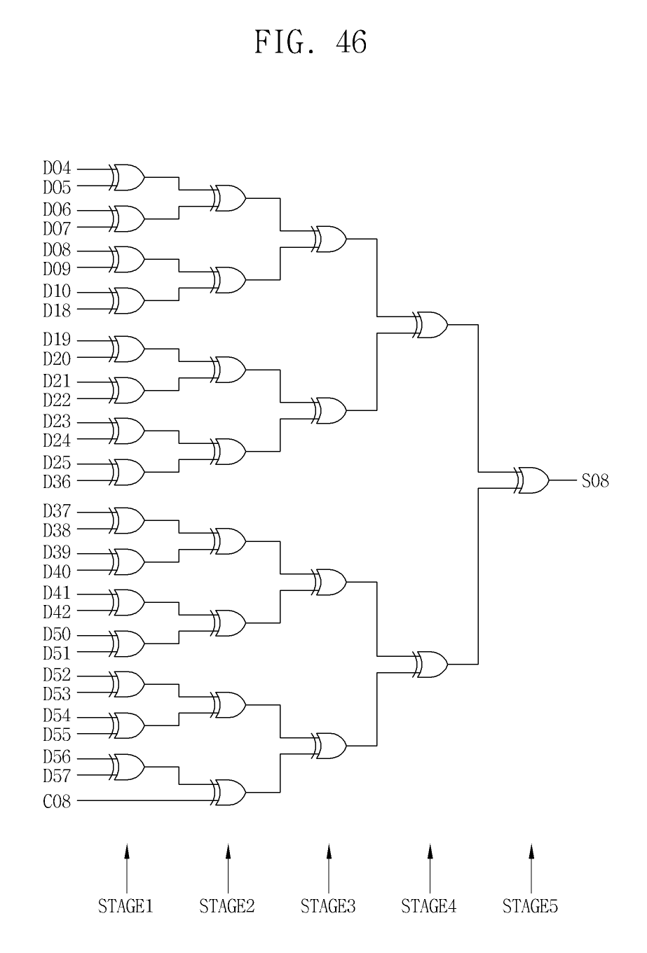

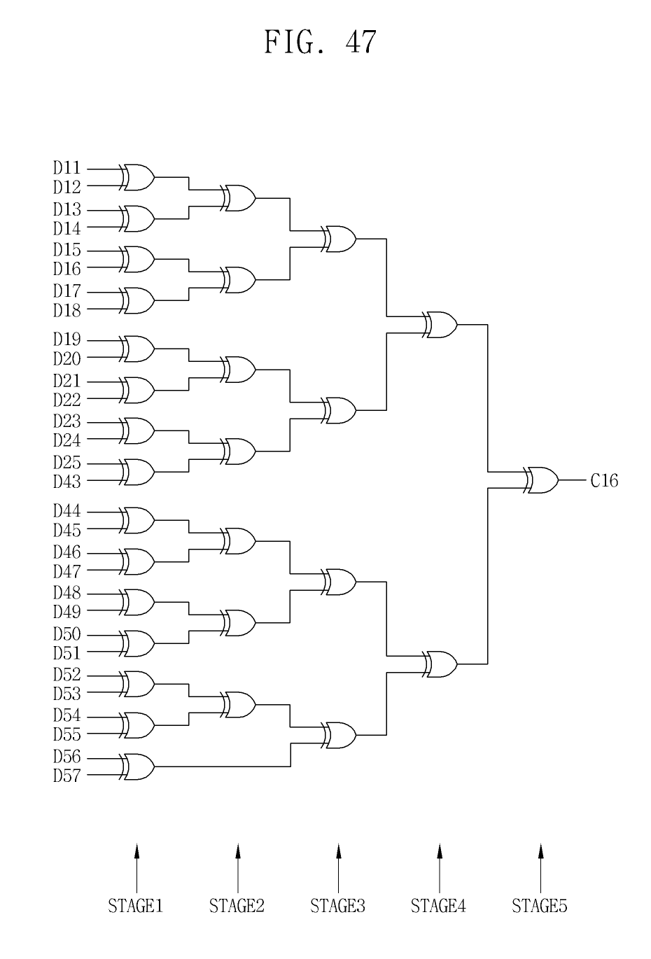

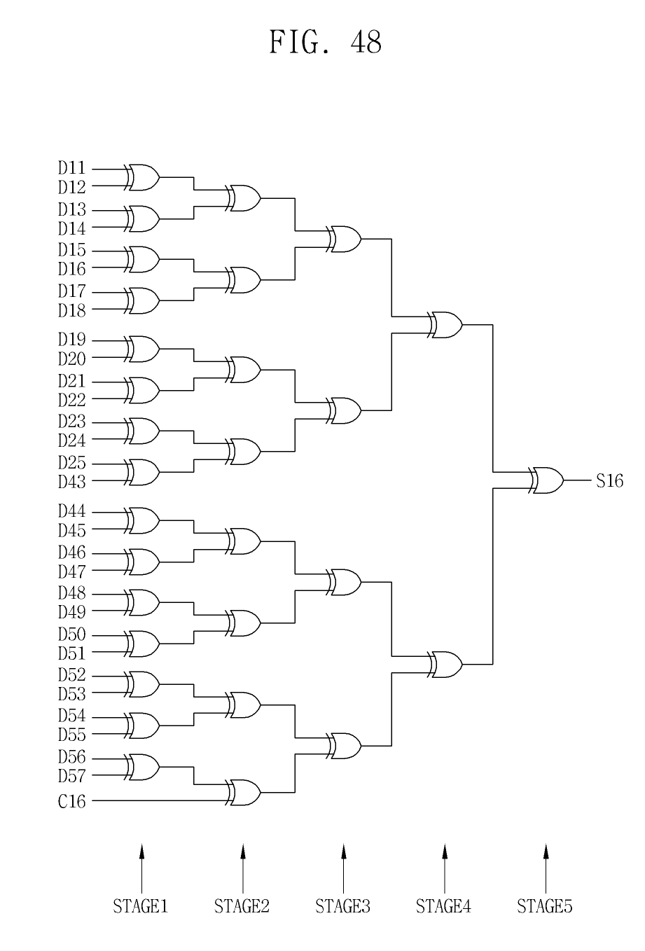

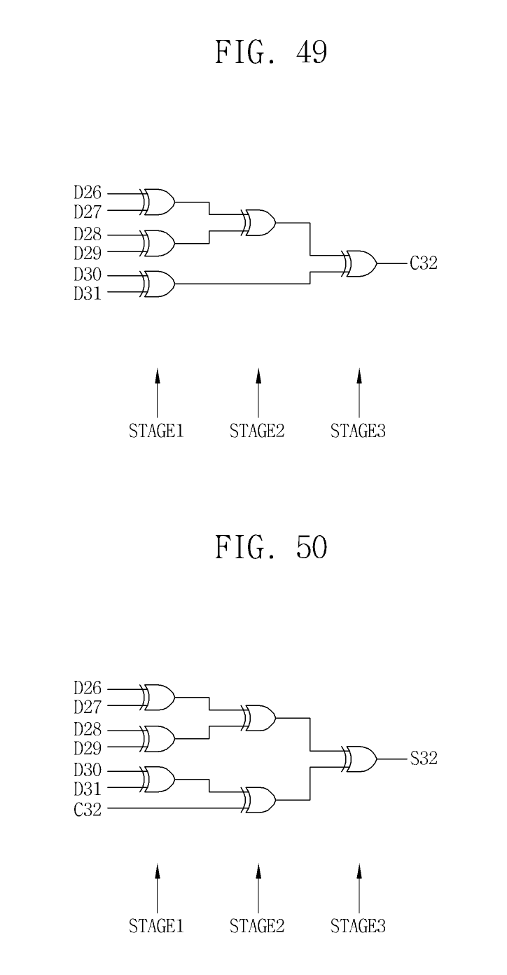

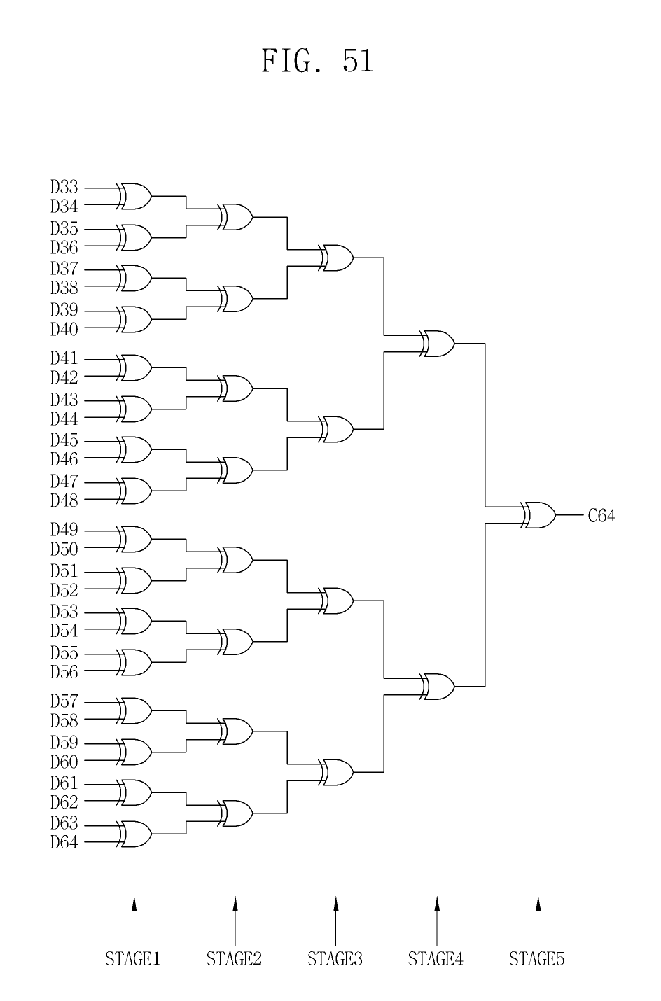

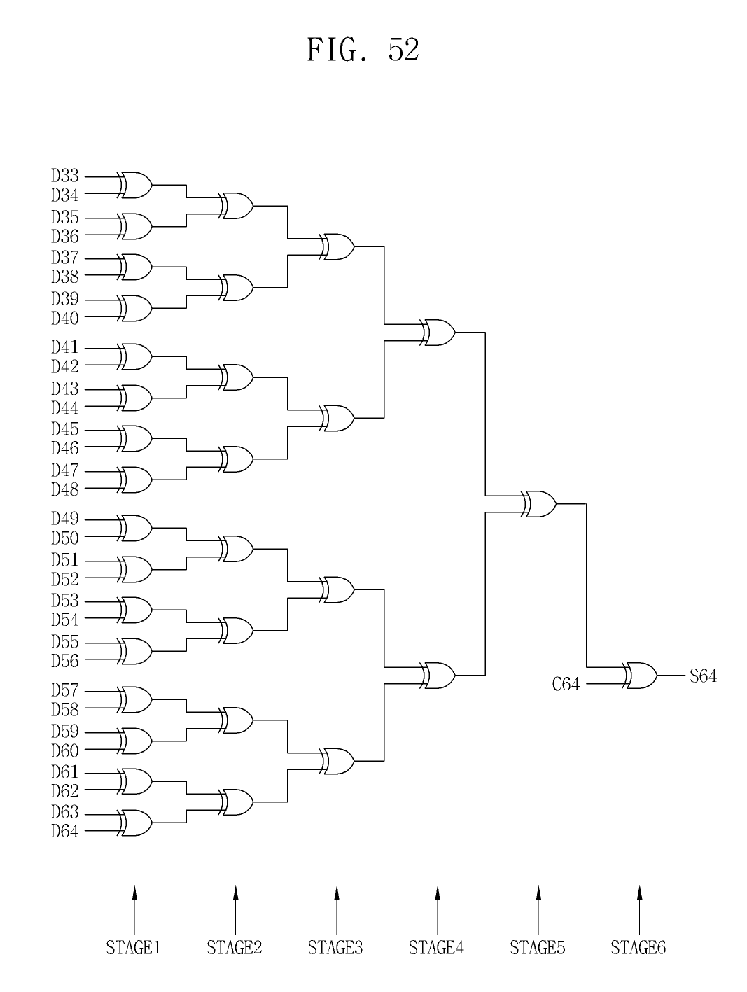

FIG. 35 is a table showing an example of a method of generating check bits using data bits shown in FIGS. 32 and 33. FIG. 36 is a table showing an example of a method of generating syndrome bits using the data bits shown in FIGS. 32 and 33. FIGS. 37 through 52 are circuit diagrams of circuits configured to generate check bits shown in FIG. 35, and syndrome bits shown in FIG. 36 using a plurality of XOR gates.

When the data bits and the check bits are disposed as shown in FIGS. 32 and 33, it can be seen that logic expressions by which the respective check bits are generated are different than in a case where the data bits and the check bits are disposed as shown in FIGS. 2 and 3.

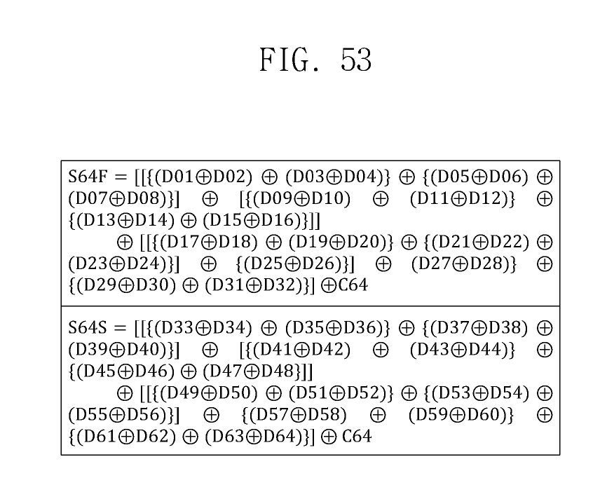

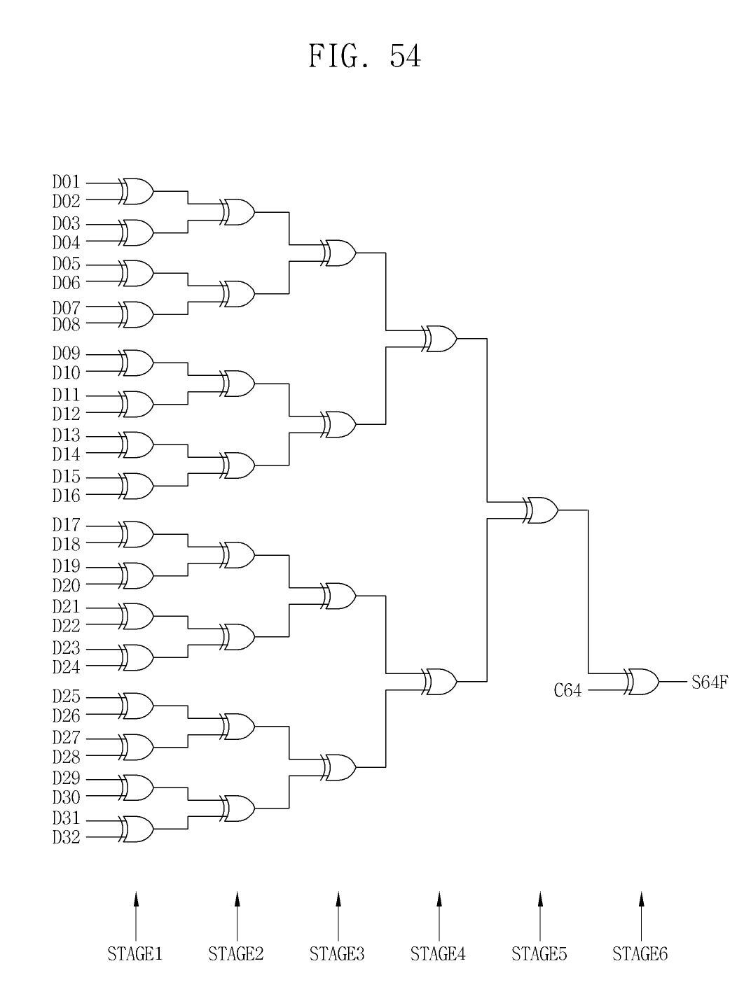

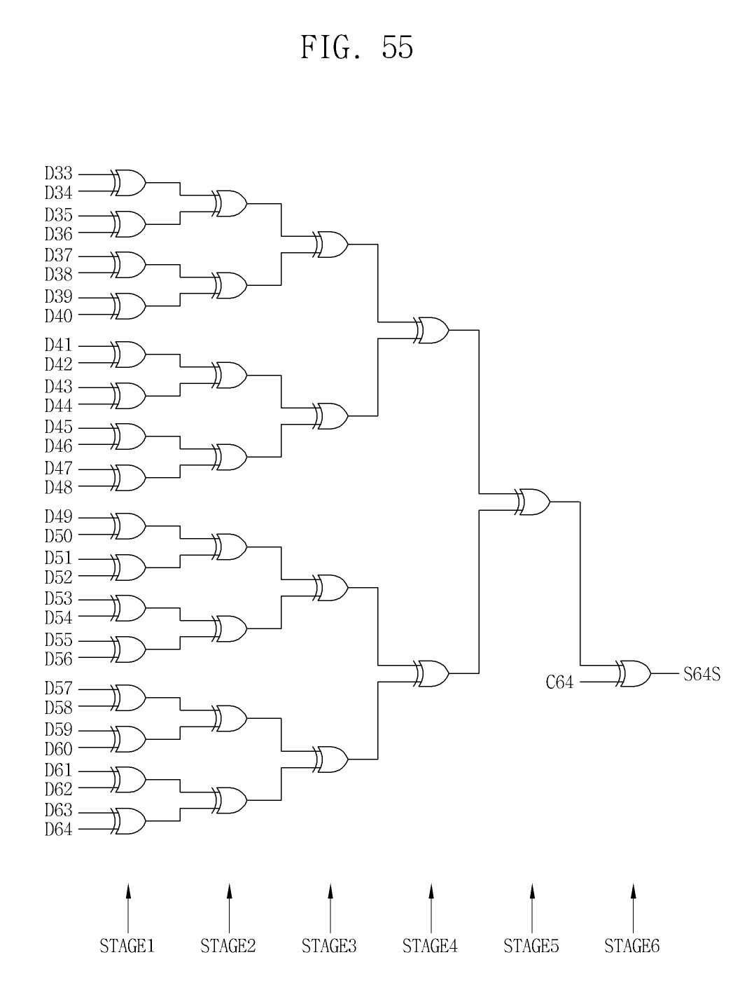

FIG. 53 is a table showing an example of a method of generating syndrome bits S64F and S64S using the data bits shown in FIGS. 32 and 33. FIGS. 54 and 55 are circuit diagrams of circuits configured to generate syndrome bits shown in FIG. 53 using a plurality of XOR gates.

Referring to FIGS. 53 through 55, the syndrome bit S64F may be obtained using data bits D01 to D32 and a check bit C64, and the syndrome bit S64S may be obtained using data bits D33 and D64 and the check bit C64.

FIG. 56 is a plan view of a memory module 200 on which a semiconductor memory device 100 is mounted, according to embodiments of the inventive concepts.

Referring to FIG. 56, the semiconductor module 200 according to the embodiments of the inventive concepts may include a module substrate 210, a plurality of semiconductor memory devices 220, and a control chip package 230. I/O terminals 240 may be formed in the module substrate 210. The semiconductor memory devices 220 may generate check bits and syndrome bits, and correct errors using the above-described methods according to the embodiments of the inventive concepts.

The semiconductor memory devices 220 and the control chip package 230 may be mounted on the module substrate 210. The semiconductor memory devices 220 and the control chip package 230 may be electrically connected, for example, in series or parallel to the I/O terminals 240.

In applied embodiments, the semiconductor module 200 may not include the control chip package 230. The semiconductor memory devices 220 may include a volatile memory chip, such as a dynamic random access memory (DRAM) or a static random access memory (SRAM), a non-volatile memory chip, such as a flash memory, a phase-change memory, a magnetic random access memory (MRAM), or a resistive random access memory (RRAM), or a combination thereof.

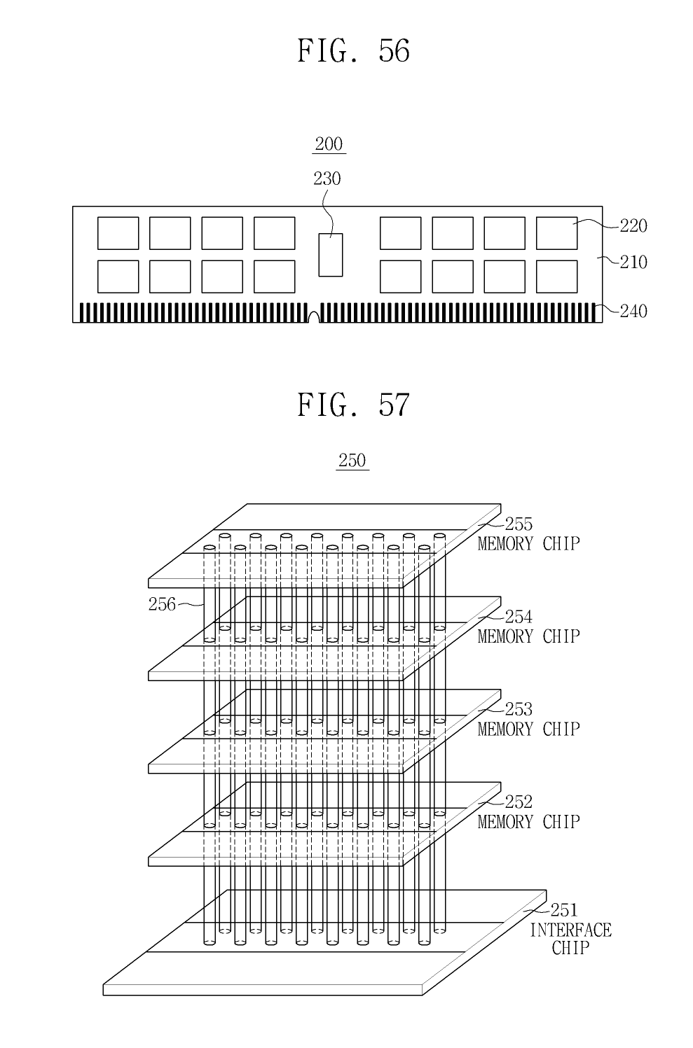

FIG. 57 is a simplified perspective view of one of stack semiconductor devices 250 including semiconductor memory devices 100 according to embodiments of the inventive concepts.

Referring to FIG. 57, the stack semiconductor devices 250 may include an interface chip 251, and memory chips 252, 253, 254, and 255 that may be electrically connected to one another using through-silicon vias (TSVs) 256. Although FIG. 57 illustrates the TSVs 256 arranged in two rows, the stack semiconductor device 250 may include an arbitrary number of TSVs.

The memory chips 252, 253, 254, and 255 included in the stack semiconductor device 250 may generate check bits and syndrome bits, and correct errors using the above-described methods according to the embodiments of the inventive concepts. Also, when each of the memory chips 252, 253, 254, and 255 have a data ordering function, one or a plurality of syndrome bits generated during the drive of an error checking and correcting (ECC) engine may be combined with data ordering information, and combination results may be used to correct data errors. The interface chip 251 may function as an interface between the memory chips 252, 253, 254, and 255 and an external apparatus.

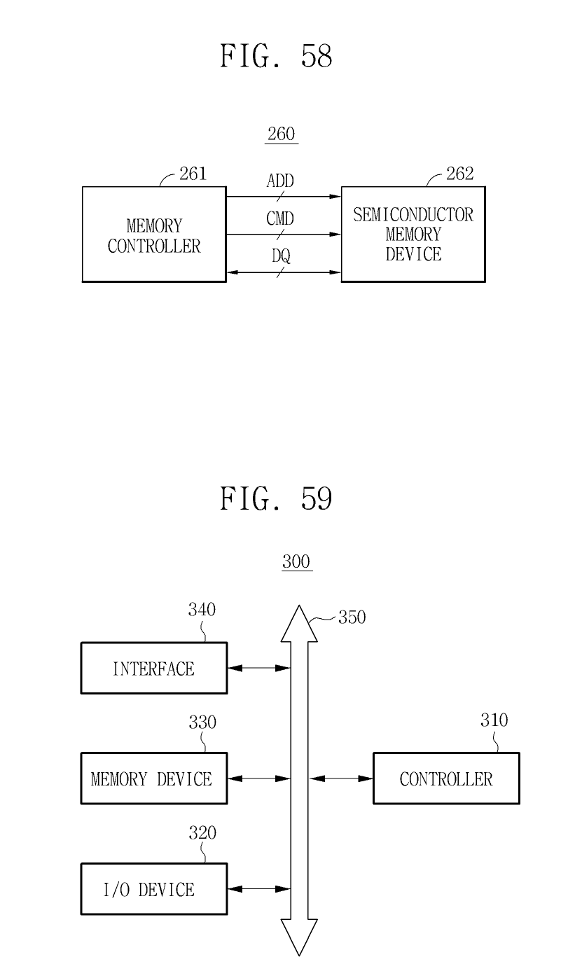

FIG. 58 is a block diagram of an example of a memory system 260 including a semiconductor memory device 100 according to embodiments of the inventive concepts.

Referring to FIG. 58, the memory system 260 may include a memory controller 261 and a semiconductor memory device 262.

The memory controller 261 may generate an address signal ADD and a command CMD, and provide the address signal ADD and the command CMD to the semiconductor memory device 262 through data buses providing communication between the memory controller 261 and the memory device 262 (not illustrated). Data DQ may be transmitted from the memory controller 261 to the semiconductor memory device 262 through the data buses, or transmitted from the semiconductor memory device 262 to the memory controller 261 through the buses.

The semiconductor memory device 262 may generate check bits and syndrome bits, and correct errors using the above-described methods according to the embodiments of the inventive concepts.

FIG. 59 is a block diagram of an example of an electronic system 300 including a semiconductor memory device 100 according to embodiments of the inventive concepts.

Referring to FIG. 59, the electronic system 300 according to the embodiments of the inventive concepts may include a controller 310, an I/O device 320, a memory device 330, an interface 340, and a bus 350. The bus 350 may provide a path through which the controller 310, the I/O device 320, the memory device 330, and the interface 340 may transmit/receive data to/from one another.

The controller 310 may include one of a microprocessor (MP), a digital signal processor (DSP), a microcontroller (MC), and at least one of logic devices capable of similar functions thereto. The I/O device 320 may include at least one selected out of a keypad, a keyboard, and a display device. The memory device 330 may store data and/or commands executed by the controller 310.

The memory device 330 may include a volatile memory chip, such as a DRAM or an SRAM, a non-volatile memory chip, such as a flash memory, a phase-change memory, an MRAM, or an RRAM, or a combination thereof. The memory device 330 may generate check bits and syndrome bits, and correct data errors using the above-described methods according to the embodiments of the inventive concepts.

The interface 340 may serve to transmit/receive data to/from a communication network. The interface 340 may include an antenna or a wired/wireless transceiver and transmit and receive data by wires or wirelessly. Also, the interface 340 may include, for example, optical fibers and transmit and receive data through the optical fibers. The electronic system 300 may further include, for example, any or all of an application chipset, a camera image processor (CIP), and an I/O device.

The electronic system 300 may be embodied by a mobile system, a personal computer (PC), an industrial computer, or a logic system capable of various functions. For example, the mobile system may be any one of a personal digital assistant (PDA), a portable computer, a web tablet, a mobile phone, a wireless phone, a laptop computer, a memory card, a digital music system, and a data transmission/receiving system. When the electronic system is an apparatus capable of wireless communications, the electronic system 300 may be used for or with a communication system, such as code division multiple access (CDMA), global system for mobile communication (GSM), North American digital cellular (NADC), enhanced-time division multiple access (E-TDMA), wideband code division multiple access (WCDMA), or CDMA2000.

Embodiments of the inventive concepts include, for example, a semiconductor device, particularly, a semiconductor memory device and a memory module and memory system including the same.

A semiconductor memory device according to embodiments of the inventive concepts can generate an additional check bit in addition to normal check bits, generate an additional syndrome bit in addition to normal syndrome bits, and correct errors. Thus, the semiconductor memory device according to the embodiments of the inventive concepts can have a small chip size and high operating speed and reliability.

Furthermore, when the semiconductor memory device according to the embodiments of the inventive concepts has an even-first data output structure or an odd-first data output structure, one of syndrome bits S64S and S64F can be selected based on ordering information, and errors in data can be corrected using the selected syndrome bit S64S or S64F.

Example embodiments of the inventive concepts having thus been described, it will be obvious that the same may be varied in many ways. Such variations are not to be regarded as a departure from the intended spirit and scope of example embodiments of the inventive concepts, and all such modifications as would be obvious to one skilled in the art are intended to be included within the scope of the following claims.

What is claimed is:

1. A semiconductor memory device comprising:
a check bit generator configured to generate check bits based on input data;
a memory cell array configured to store combined data, the combined data including the input data and the check bits;
an error calculator configured to generate syndrome bits based on first data and the check bits received from the memory cell array, and calculate an error based on the syndrome bits to generate error data; and
an error corrector configured to correct the first data based on the first data and the error data, and generate second data,
wherein the check bit generator is configured to generate one or more normal check bits and one or more additional check bits, and the error calculator is configured to generate one or more normal syndrome bits and one or more additional syndrome bits, the additional check bits not being normal check bits, and the additional syndrome bits not being normal syndrome bits.

2. The device of claim 1, wherein a logic expression of the one or more additional syndrome bits has common elements that construct logic expressions of the one or more normal syndrome bits.

3. The device of claim 1, wherein the error calculator includes a syndrome bit generating circuit configured to generate the one or more normal syndrome bits and one or more additional syndrome bits based on the first data and the check bits.

4. The device of claim 1, wherein, the memory cell array is configured to store the combined data such that the one or more normal check bits are disposed in positions having position numbers in the combined data which are powers of 2, and the one or more additional check bits are not disposed in positions having position numbers in the combined data which are powers of 2.

5. The device of claim 4, wherein the check bit generator is configured such that the one or more normal check bits include check bits C01, C02, C04, C08, C16, C32, and C64, and the one or more additional check bits include a check bit C07.

6. The device of claim 5, wherein the check bit generator is configured to perform an exclusive OR (XOR) logic operation on selected data bits to generate the additional check bit C07, the selected data bits being data bits having position numbers within the combined data that correspond to binary numbers in which the three least significant bits represent the decimal number 7.

7. The device of claim 5, wherein the check bit generator compares data bits except for data bits having position numbers within the combined data that correspond to binary numbers in which the three least significant bits represent the decimal number 7, and generates the check bits C01, C02, and C04.

8. The device of claim 1, wherein the memory cell array is configured to store the combined data such that the one or more normal check bits are disposed in positions having position numbers in the combined data which are powers of 2, and the one or more additional check bits are not disposed in positions having position numbers in the combined data which are powers of 2, and
wherein the error calculator is configured to generate the one or more normal syndrome bits and the one or more additional syndrome bits such that each of the normal syndrome bits correspond to one of the normal check bits, and each of the additional syndrome bits corresponds to one of the additional check bits.

9. The device of claim 8, wherein the error calculator is configured such that the one or more normal syndrome bits include syndrome bits S01, S02, S04, S08, S16, S32, and S64, and the one or more additional syndrome bits include a syndrome bit S07.

10. The device of claim 9, wherein the error calculator is configured such that one or more of the one or more normal syndrome bits are combined with data ordering information, and combination results are used to correct the error data.

11. The device of claim 9, wherein the number of all the syndrome bits including the additional syndrome bits is equal to the smallest unit of data quantity simultaneously output during a dynamic random access memory (DRAM) core operation.

12. The device of claim 11, wherein the error calculator is configured such that the syndrome bit S64 includes a syndrome bit S64F obtained based on even data, and a syndrome bit S64S obtained based on odd data.

13. The device of claim 12, wherein the error calculator is configured to select one of the syndrome bits S64S and S64F based on ordering information including information regarding even-first data or odd-first data, and correct the error data based on the selected syndrome bit S64S or S64F.

14. A method of correcting an error in a semiconductor memory device configured to perform data write and read operations based on a plurality of syndrome bits by dividing even data from odd data, and use a data ordering scheme, the method comprising:
generating a most significant syndrome bit S64F, from among the plurality of syndrome bits, using the even data;
generating a most significant syndrome bit S64S, from among the plurality of syndrome bits, using the odd data;
generating remaining syndrome bits, from among the plurality of syndrome bits, using data output in the same order out of the even data and the odd data; and
correcting data errors using the syndrome bits.

15. The method of claim 14, wherein based on ordering information, when the semiconductor memory device has an even-first input/output data (I/O) structure and outputs data, the error data is corrected using the syndrome bit S64S, and when the semiconductor memory device has an odd-first data I/O structure and outputs data, the error data is corrected using the syndrome bit S64F.

16. A semiconductor memory device comprising:
a check bit generator configured to generate a plurality of check bits based on input data;
a memory cell array configured to store combined data, the combined data including the input data and the plurality of check bits, each bit in the combined data being placed at different one of a plurality of sequentially numbered bit positions within the combined data,
wherein the plurality of check bits include one or more normal check bits having bit positions, from among the plurality of bit positions, the numbers of which are powers of 2, and the plurality of check bits include additional check bits having bit positions, from among the plurality of bit positions, the numbers of which are not powers of 2.

17. The device of claim 16, further comprising:
an error calculator configured to generate syndrome bits based on data read from the memory cell array, and to determine an error in the read data based on the syndrome bits to generate error data, the read data including first data and one or more check bits, each of the syndrome bits being generated based on a corresponding one of the plurality of check bits, respectively,
wherein the error calculator is configured such that the generated syndrome bits include one or more normal syndrome bits and one or more additional syndrome bits, each of the normal syndrome bits being a syndrome bit generated based on a corresponding normal check bit from among the plurality of check bits, each of the additional syndrome bits being a syndrome bit generated based on a corresponding additional check bit from among the plurality of check bits.
